(19) United States
(12) Patent Application Publication
(10) Pub. No.: US 2026/0333718 A1
(43) Pub. Date: Oct. 22, 2026

(54) INTEGRATED CHIP AND METHOD OF MANUFACTURING THE SAME

(71) Applicant: Taiwan Semiconductor Manufacturing Company, Ltd., Hsinchu (TW)

(72) Inventors: Chieh-En Chen, Tainan City (TW); Chen-Hsien Lin, Tainan City (TW); Shyh-Fann Ting, Tainan City (TW)

(21) Appl. No.: 19/185,369

(22) Filed: Apr. 22, 2025

(51) Int. Cl. H10D 1/68; H01L 23/522; H01L 25/00; H01L 25/07; H10D 1/00; H10D 80/20; H10D 84/80; H10D 88/00

(52) U.S. Cl. CPC H10D 1/692; H10D 1/042; H10D 1/043; H10D 80/215; H10D 84/813; H10D 88/00; H10D 88/01; H10W 20/496; H10W 90/00

(57) ABSTRACT

An integrated chip includes a semiconductor substrate. The integrated chip includes a first conductive interconnect over the semiconductor substrate. The integrated chip includes a first dielectric structure on the first conductive interconnect. The integrated chip includes a first conductive layer beside the first dielectric structure and extending from the first conductive interconnect to above the first dielectric structure. The integrated chip includes an insulator layer over the first conductive layer and the first dielectric structure. The integrated chip includes a second conductive layer over the insulator layer and the first dielectric structure. The integrated chip includes a second conductive interconnect on the second conductive layer. The first conductive layer, the insulator layer, and the second conductive layer laterally surround the first dielectric structure along sidewalls of the first dielectric structure. The insulator layer and the second conductive layer cover a top surface of the first dielectric structure.

### BACKGROUND

Many modern integrated chips include transistors as well as passive devices. Some examples of passive devices include capacitors, resistors, inductors, varactors, etc. Passive devices are widely used to control integrated chip characteristics, such as gains, time constants, etc. Some passive devices include integrated passive devices (IPDs). An IPD is a collection of one or more passive devices embedded into a single monolithic device and packaged as an integrated circuit (IC).

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1 and FIG. 2 illustrate cross-sectional views of some embodiments of a three-dimensional capacitor.

FIG. 3 and FIG. 4 illustrate top views of some embodiments of the three-dimensional capacitor of FIG. 1.

FIG. 5 and FIG. 6 illustrate cross-sectional views of some embodiments of an integrated chip including the three-dimensional capacitor of FIG. 1.

FIG. 7-10 illustrate cross-sectional views of various embodiments of the three-dimensional capacitor of FIG. 1.

FIG. 11 and FIG. 12 illustrate cross-sectional views of some other embodiments of the three-dimensional capacitor of FIG. 1.

FIG. 13 illustrates a cross-sectional view of some other embodiments of the three-dimensional capacitor of FIG. 1.

FIGS. 14-48 illustrate cross-sectional views of some embodiments of a method of forming an integrated chip including a three-dimensional capacitor.

FIG. 49 illustrates a flow diagram of some embodiments of a method of forming an integrated chip including a three-dimensional capacitor.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

An integrated chip includes a three-dimensional capacitor over a semiconductor substrate. Some three-dimensional capacitors suffer from reliability issues. For example, forming a three-dimensional capacitor often includes etching dielectric layers with one or more wet etching processes to form a trench in dielectric layers, and subsequently forming the three-dimensional capacitor in the trench. The wet etching process(es) can damage dielectric layers that surround and form the trench, which can reduce a reliability of the capacitor. Further, some three-dimensional capacitors suffer from limited design flexibility. For example, some three-dimensional capacitors have complex trench layouts with tight design constraints that can limit the design flexibility of the capacitor.

Various embodiments of the present disclosure relate to a three-dimensional capacitor having improved reliability and design flexibility. The capacitor has a grid-like layout in which a conductive layer covers sidewalls of the surrounding dielectric. This conductive layer can protect the surrounding dielectric from damage during etching. Thus, a reliability of the capacitor can be improved. Further, the grid-like layout has reduced complexity. Thus, a design flexibility of the capacitor can be improved.

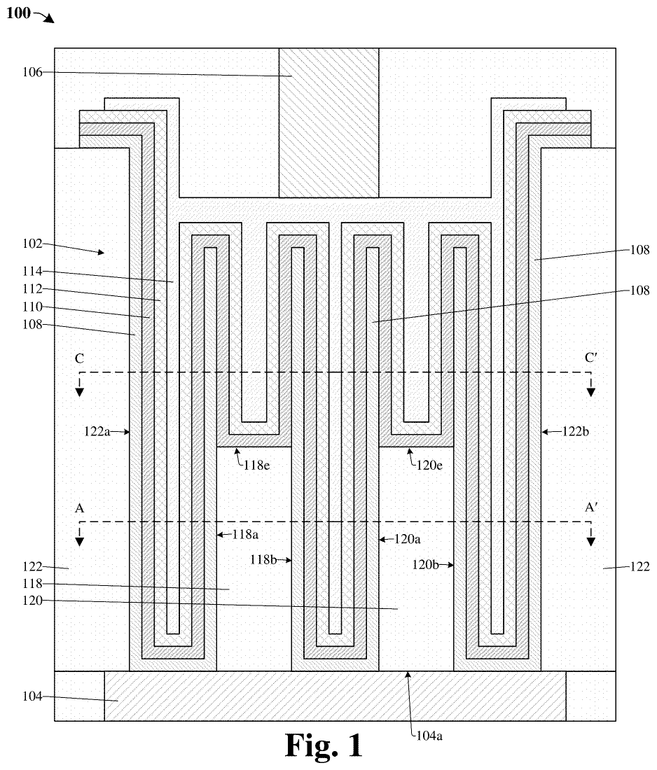

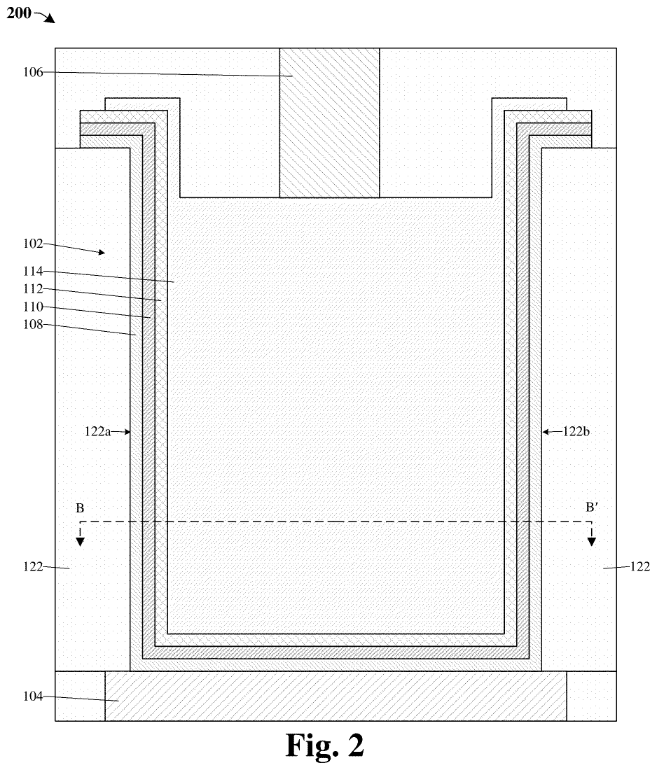

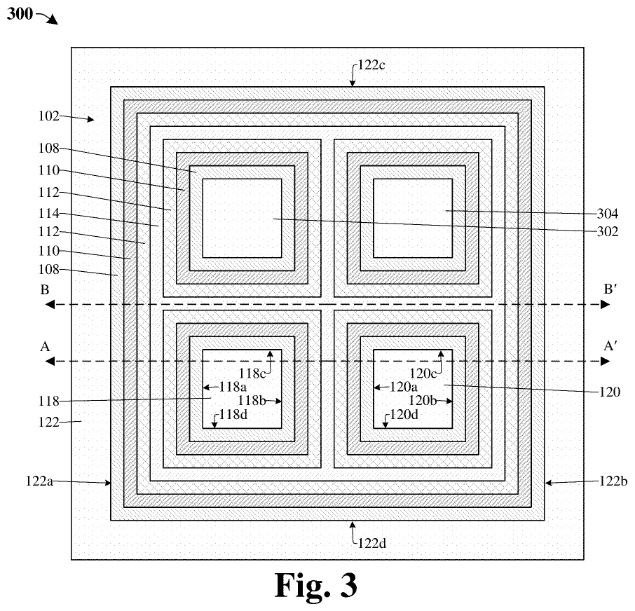

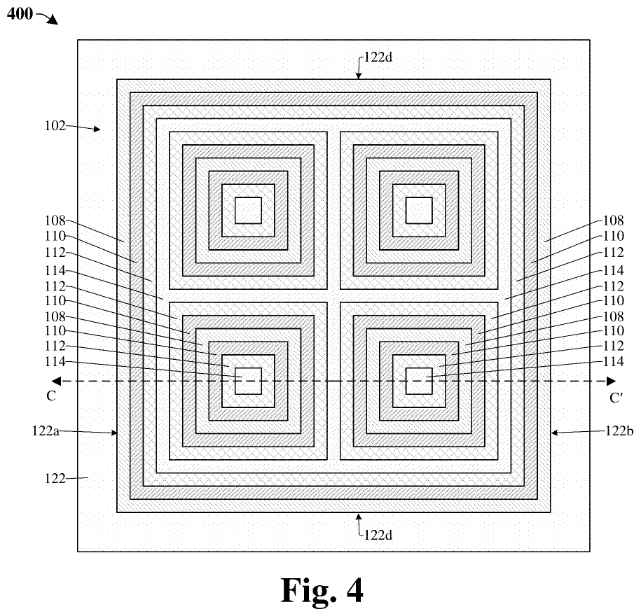

FIG. 1 illustrates a cross-sectional view 100 of some embodiments of a three-dimensional capacitor 102. FIG. 2 illustrates another cross-sectional view 200 of some embodiments of the three-dimensional capacitor 102 of FIG. 1. FIG. 3 illustrates a top view 300 of some embodiments of the three-dimensional capacitor 102 of FIG. 1. FIG. 4 illustrates another top view 400 of some embodiments the three-dimensional capacitor 102 of FIG. 1. In some embodiments, section line A-A′ of FIG. 1 corresponds to section line A-A′ of FIG. 3, section line B-B′ of FIG. 2 corresponds to section line B-B′ of FIG. 3, and section line C-C′ of FIG. 1 corresponds to section line C-C′ of FIG. 4.

The capacitor 102 is over a first conductive interconnect 104 (e.g., a conductive line). A second conductive interconnect 106 (e.g., a conductive via) is over the capacitor 102. The capacitor 102 includes a first conductive layer 108, a second conductive layer 110 over the first conductive layer 108, a third conductive layer 114 over the second conductive layer 110, and an insulator layer 112 between the second conductive layer 110 and the third conductive layer 114. The first conductive layer 108 and the second conductive layer 110 form a bottom electrode of the capacitor 102 and are coupled to the first conductive interconnect 104. The third conductive layer 114 forms a top electrode of the capacitor 102 and is coupled to the second conductive interconnect 106.

Dielectric pillar structures 118, 120, 302, 304 are laterally spaced apart on the first conductive interconnect 104. An outer dielectric structure 122 (e.g., a dielectric enclosure) surrounds the dielectric pillars and the capacitor 102. Sidewalls 122a, 122b, 122c, 122d of the outer dielectric structure 122 delimit an outer boundary of the capacitor 102.

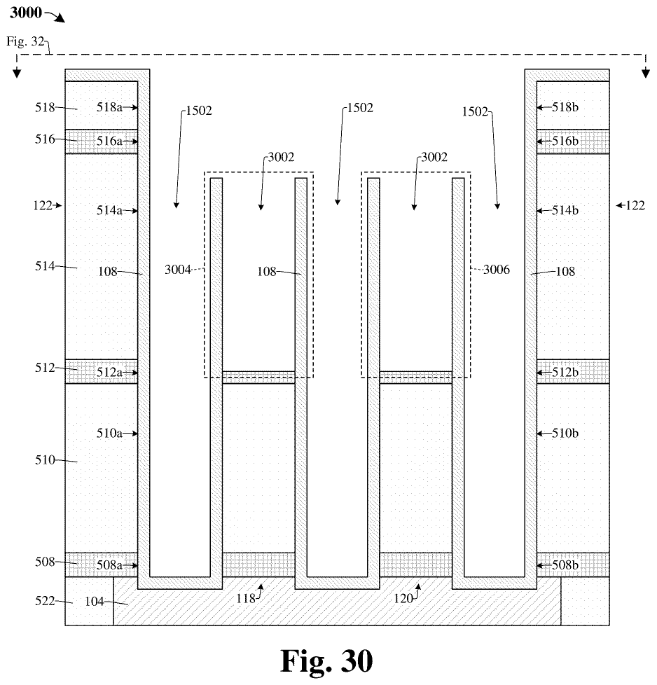

The first conductive layer 108 covers the sidewalls 122a, 122b, 122c, 122d of the outer dielectric structure 122. Thus, the first conductive layer 108 can protect the outer dielectric structure 122 from damage during the formation of the dielectric pillars 118, 120, 302, 304, as explained in further detail with reference to FIGS. 30-32. As a result, a reliability of the integrated chip can be improved.

The first conductive layer 108 covers sidewalls of the dielectric pillars 118, 120, 302, 304. For example, the first conductive layer covers sidewalls 118a, 118b, 118c, 118d of the first dielectric pillar 118, sidewalls 120a, 120b, 120c, 120d of the second dielectric pillar 120, and so on. Further, the first conductive layer 108 extends upward above the tops of the dielectric pillars 118, 120, 302, 304. The first conductive layer 108 extends continuously from the sidewalls 122a, 122b, 122c, 122d of the outer dielectric structure 122 to an upper surface 104a of conductive interconnect 104 and to the sidewalls (e.g., sidewalls 118a, 118b, 118c, 118d, 120a, 120b, 120c, 120d, etc.) of the dielectric pillars 118, 120, 302, 304. Because the first conductive layer 108 has this continuity, a structural integrity of the first conductive layer 108 may be improved, as explained in further detail with reference to FIGS. 30-32. Thus, a reliability of the integrated chip can be further improved.

The second conductive layer 110 conformally lines sidewalls and upper surfaces of the first conductive layer 108. Further, the second conductive layer 110 covers top surfaces of the dielectric pillars 118, 120, 302, 304. For example, the second conductive layer 110 covers a top surface 118e of the first dielectric pillar 118, a top surface 120e of the second dielectric pillar 120, and so on.

The insulator layer 112 conformally lines sidewalls and upper surfaces of the second conductive layer 110. The third conductive layer 114 conformally lines sidewalls and upper surfaces of the insulator layer 112 and fills out a remainder of the trench in which the capacitor 102 is arranged. Together, the first conductive layer 108, the second conductive layer 110, the insulator layer 112, and the third conductive layer 114 laterally surround, and extend directly between, the dielectric pillars 118, 120, 302, 304 in a grid-like fashion. The simplicity of this grid-shaped layout can improve the design flexibility of the capacitor 102.

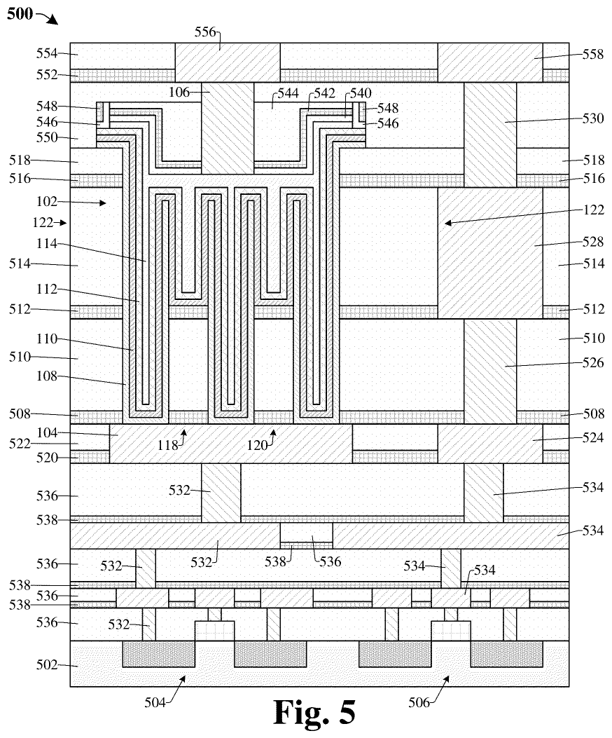

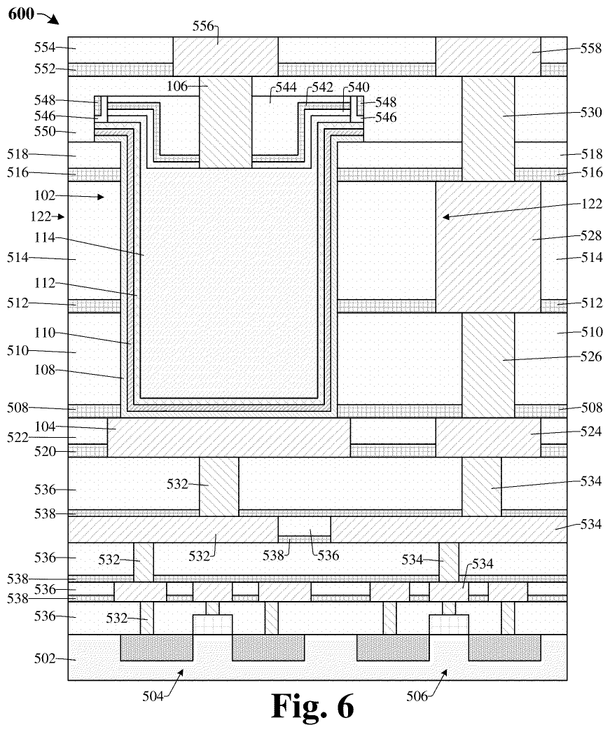

FIG. 5 and FIG. 6 illustrate cross-sectional view 500 and cross-sectional view 600, respectively, of some embodiments of an integrated chip including the capacitor 102 of FIG. 1 and FIG. 2.

The integrated chip includes transistor devices 504, 506 along a semiconductor substrate 502. The three-dimensional capacitor 102 is over the semiconductor substrate 502. Dielectric layers 510, 514, 518 and etch stop layers 508, 512, 516 are over the semiconductor substrate 502. The dielectric pillars 118, 120 are formed by etch stop layer 508, dielectric layer 510, and etch stop layer 512. The outer dielectric structure 122 is formed by dielectric layers 510, 514, 518 and etch stop layers 508, 512, 516.

Conductive interconnect 104 is between sidewalls of etch stop layer 520 and dielectric layer 522. Conductive interconnects (e.g., conductive line 524, conductive via 526, conductive line 528, and conductive via 530) are laterally spaced from conductive interconnects 104, 106 and the capacitor 102. Conductive interconnects 532, 534 (e.g., conductive lines, conductive vias, conductive contacts, conductive pads, or the like), dielectric layers 536, and etch stop layers 538 are between the semiconductor substrate 502 and conductive interconnects 104, 524. For example, conductive interconnects 532 couple transistor device 504 to conductive interconnect 104, and conductive interconnects 534 couple transistor device 506 to conductive interconnect 524.

Dielectric layers 540, 544, 546, 550 and etch stop layers 542, 548 are over the capacitor 102 and surround conductive interconnect 106. Conductive interconnect 556 is over and coupled to conductive interconnect 106. Conductive interconnect 558 is over and coupled to conductive interconnect 530. Etch stop layer 552 and dielectric layer 554 surround conductive interconnects 556, 558.

In some embodiments, the semiconductor substrate 502 comprises silicon or some other suitable material. In some embodiments, the transistor devices 504, 506 are or comprise bipolar junction transistors, metal-oxide-semiconductor field-effect transistors, junction field effect transistors, fin field-effect transistors, gate all-around transistors, or some other suitable transistors. In some embodiments, dielectric layers 536, 522, 510, 514, 518, 540, 544, 546, 550, 554 comprise silicon oxide or some other suitable material. In some embodiments, etch stop layers 538, 520, 508, 512, 516, 542, 548, 552 comprise silicon nitride, silicon carbide, or some other suitable material. In some embodiments, conductive interconnects 532, 534, 524, 526, 528, 558, 104, 106, 556 comprise copper, tungsten, aluminum, or some other suitable material. In some embodiments, the first conductive layer 108 comprises titanium nitride, tantalum, tantalum nitride, a combination of the foregoing, or some other suitable material. In some embodiments, the second conductive layer 110 and the third conductive layer 114 comprise titanium nitride or some other suitable material. In some embodiments, the insulator layer 112 comprises a high k dielectric such as, for example, hafnium oxide, tantalum oxide, aluminum oxide, or some other suitable material.

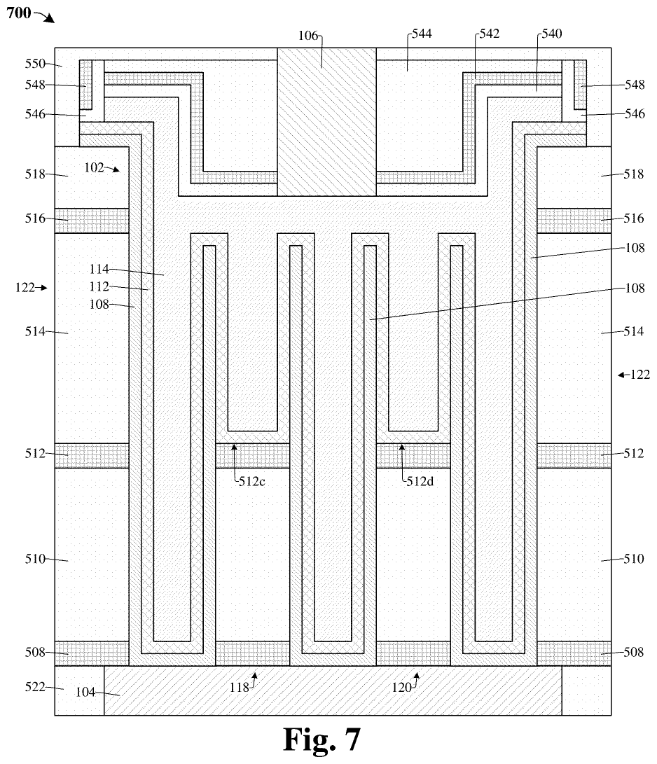

FIG. 7 illustrates cross-sectional view 700 of some other embodiments of the capacitor 102 of FIG. 1 in which the second conductive layer 110 is omitted from the capacitor 102.

The insulator layer 112 is directly on the first conductive layer 108. Further, the insulator layer 112 is directly on tops of the dielectric pillars 118, 120. For example, the insulator layer 112 covers a top surface 512c of the portion of etch stop layer 512 that forms the first dielectric pillar 118 and covers a top surface 512d of the portion of etch stop layer 512 that forms the second dielectric pillar 120. In some cases, by excluding the second conductive layer 110 and disposing the insulator layer 112 directly on the first conductive layer 108, a cost of the integrated chip can be reduced and/or a process time for forming the integrated chip can be reduced.

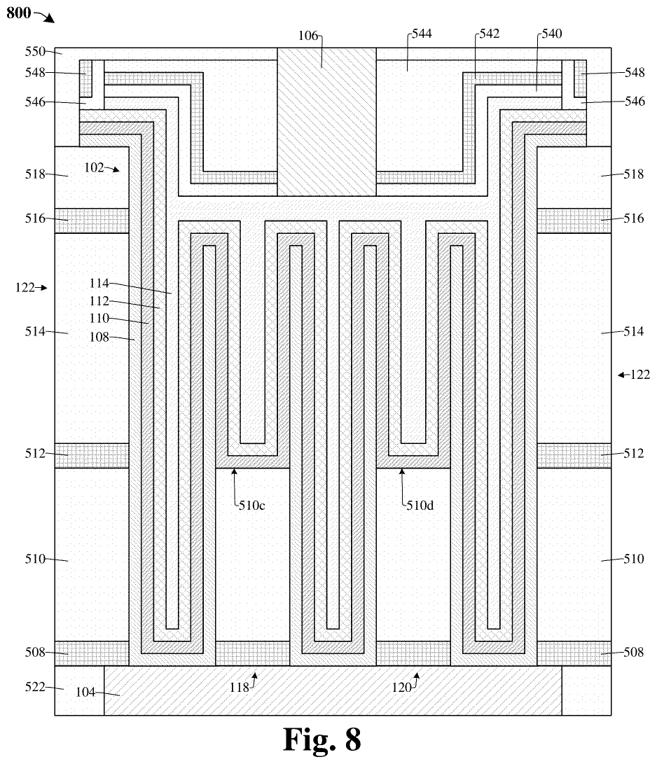

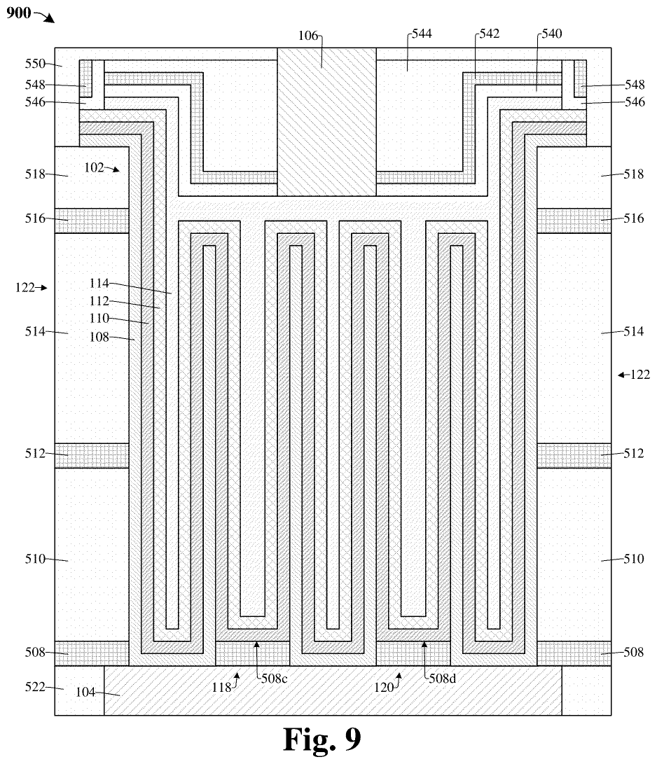

FIG. 8 and FIG. 9 illustrate cross-sectional view 800 and a cross-sectional view 900, respectively, of some other embodiments of the capacitor of FIG. 1.

In some embodiments (e.g., as illustrated in FIG. 8), the dielectric pillars 118, 120 are formed by etch stop layer 508 and dielectric layer 510. For example, a top surface 510c of a first portion of dielectric layer 510 forms a top of dielectric pillar 118 and a top surface 510d of a second portion of dielectric layer 510 forms a top of dielectric pillar 120. Thus, the heights of the dielectric pillars 118, 120 can be reduced. As a result, the surface area between the first electrode (e.g., the first and second conductive layers 108, 110) and the second electrode (e.g., the third conductive layer 114) of the capacitor 102 can be increased. Thus, a capacitance of the capacitor 102 can be increased.

In some embodiments (e.g., as illustrated in FIG. 9), the dielectric pillars 118, 120 are formed by etch stop layer 508. For example, a top surface 508c of a first portion of etch stop layer 508 forms a top of dielectric pillar 118 and a top surface 508d of a second portion of etch stop layer 508 forms a top of dielectric pillar 120. Thus, the heights of the dielectric pillars 118, 120 can be further reduced. As a result, the surface area between the first electrode (e.g., the first and second conductive layers 108, 110) and the second electrode (e.g., the third conductive layer 114) directly over the dielectric pillars can be further increased and thus a capacitance of the capacitor 102 can be further increased.

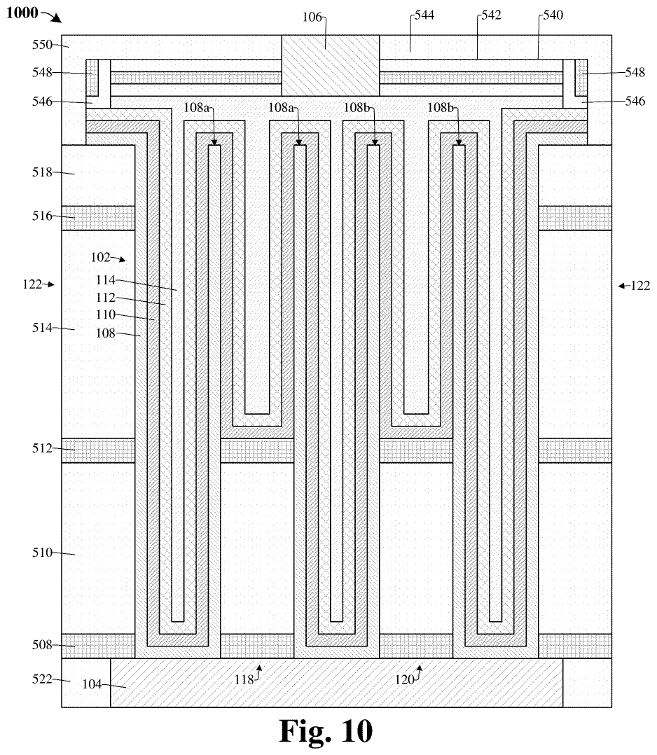

FIG. 10 illustrates a cross-sectional view 1000 of some other embodiments of the capacitor 102 of FIG. 1.

A top surface 108a of the portion of the first conductive layer 108 that covers sidewalls of the first dielectric pillar 118 and a top surface 108b of the portion of the first conductive layer 108 that cover sidewalls of the second dielectric pillar 120 are above a top surface of etch stop layer 516. Thus, the surface area between the first electrode (e.g., the first and second conductive layers 108, 110) and the second electrode (e.g., the third conductive layer 114) can be increased and a capacitance of the capacitor 102 can be increased. In some such embodiments, the third conductive layer 114 has a substantially planar top surface.

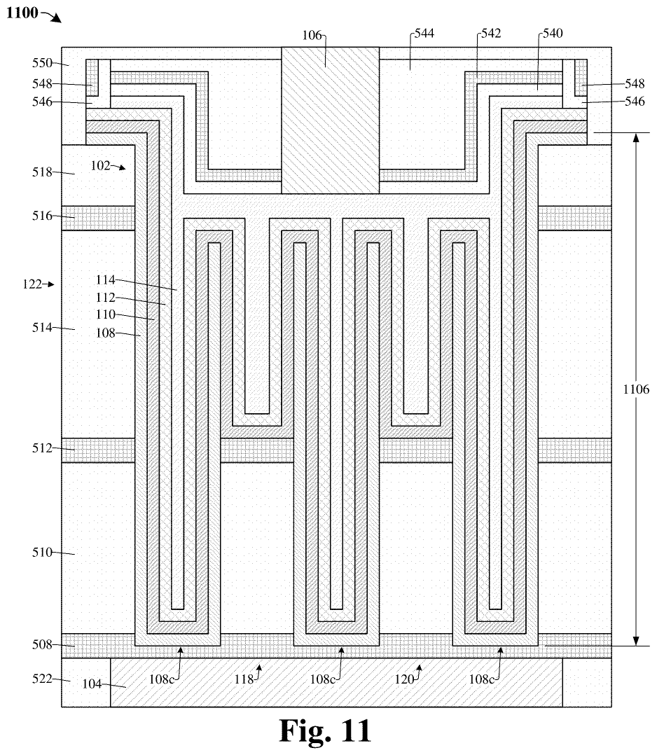

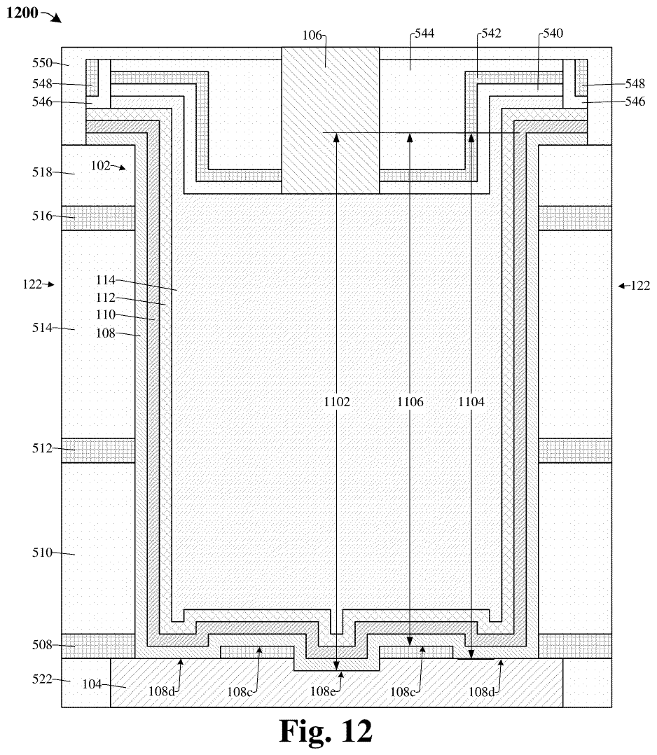

FIG. 11 and FIG. 12 illustrate cross-sectional view 1100 and cross-sectional view 1200, respectively, of some other embodiments of the capacitor 102 of FIG. 1 and FIG. 2.

The capacitor 102 reaches a first depth 1102 (e.g., as measured from a topmost surface of conductive layer 108) at the inner “intersections” (e.g., “four-way” intersections) of the “streets” of the grid formed by the capacitor 102. The capacitor 102 reaches a second depth 1104, less than the first depth 1102, at outer “intersections” (e.g., “three-way” intersections) of the “streets” of the grid. The capacitor 102 reaches a third depth 1106, less than the second depth 1104, between the “intersections” of the grid.

In some embodiments, the third depth 1106 is less than the depth of the top surface of conductive interconnect 104 such that lower surfaces 108c of the first conductive layer 108 (e.g., where the capacitor 102 has the third depth 1106) are spaced over the top surface of conductive interconnect 104. In some embodiments, the second depth 1104 is approximately equal to the depth of the top surface of conductive interconnect 104 such that lower surfaces 108d of the first conductive layer 108 (e.g., where the capacitor 102 has the second depth 1104) are directly on the top surface of conductive interconnect 104. In some embodiments, the first depth 1102 is below the depth of the top surface of conductive interconnect 104 such that lower surface 108e of the first conductive layer 108 (e.g., where the capacitor 102 has the first depth 1102) is below the top surface and between sidewalls of conductive interconnect 104.

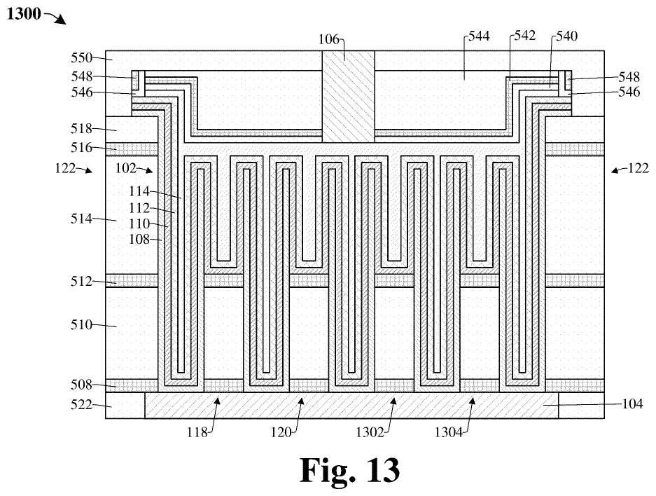

FIG. 13 illustrates a cross-sectional view 1300 of some other embodiments of the capacitor 102 of FIG. 1.

The grid formed by the capacitor 102 has five “streets” extending in one direction. Thus, there are four dielectric pillars over conductive interconnect 104 in cross-sectional view 1300, one dielectric pillar between each “street”. For example, the first dielectric pillar 118, the second dielectric pillar 120, a third dielectric pillar 1302, and a fourth dielectric pillar 1304 are laterally spaced apart along a top surface of conductive interconnect 104. The capacitor 102 (e.g., conductive layers 108, 110, 114 and insulator layer 112) laterally surrounds and covers each of the dielectric pillars. In some embodiments, the grid formed by the capacitor 102 also has five “streets” extending in the transverse direction, and there are sixteen total dielectric pillars. In some other embodiments, the grid formed by the capacitor 102 has some other dimensions (e.g., two “streets” by three “streets”, four “streets” by four “streets”, four “streets” by three “streets”, four “streets” by two “streets”, six “streets” by seven “streets”, etc.). By increasing the dimensions of the grid formed by the capacitor 102, the total capacitance of the capacitor 102 can be increased.

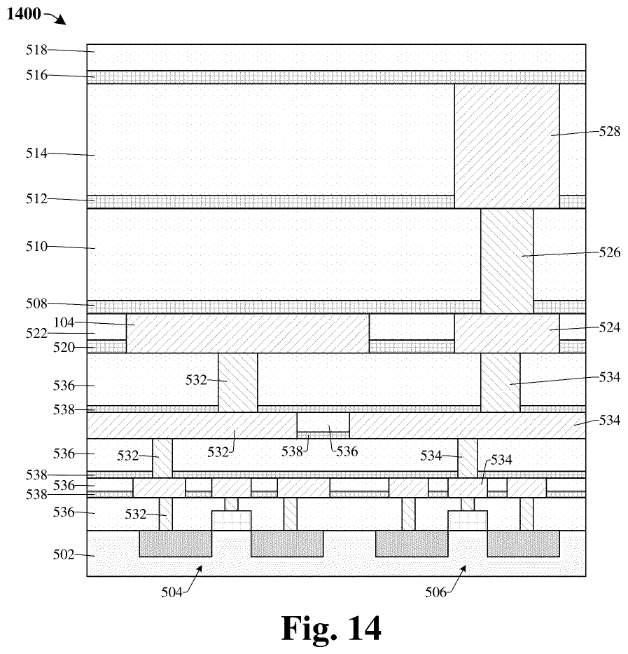

FIGS. 14-48 illustrate cross-sectional views 1400-4800 of some embodiments of a method of forming an integrated chip including a three-dimensional capacitor 102. Although FIGS. 14-48 are described in relation to a method, it will be appreciated that the structures disclosed in FIGS. 14-48 are not limited to such a method, but instead may stand alone as structures independent of the method.

As shown in cross-sectional view 1400 of FIG. 14, transistor devices 504, 506 are formed along a semiconductor substrate 502. Dielectric layers 536, 522, 510, 514, 518, etch stop layers 538, 520, 508, 512, 516, and conductive interconnects 532, 534, 104, 524, 526, 528 are formed over the semiconductor substrate 502. In some embodiments, dielectric layers 510, 514, 518 and etch stop layers 508, 512, 516 are referred to as a dielectric stack.

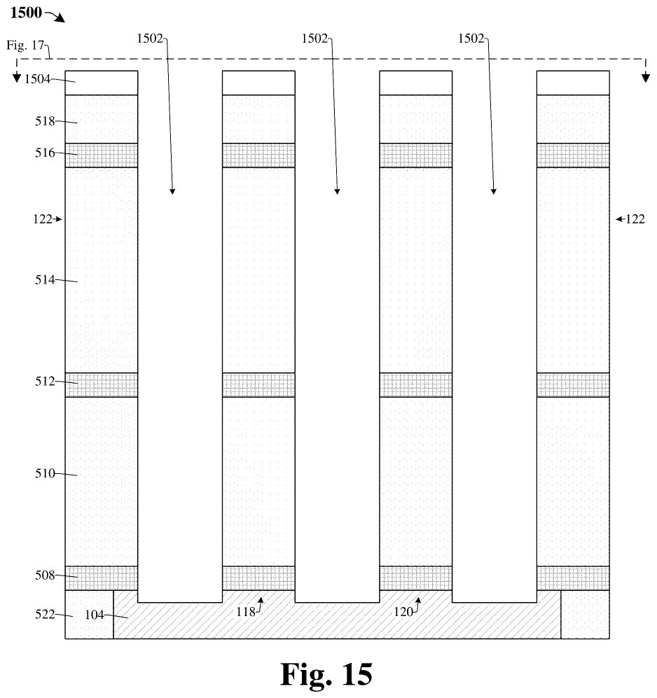

Transistors 504, 506, dielectric layers 536, etch stop layers 538, 520, and conductive interconnects 532, 534, 524, 526, 528 are not shown in FIGS. 15-46 for simplicity of illustration.

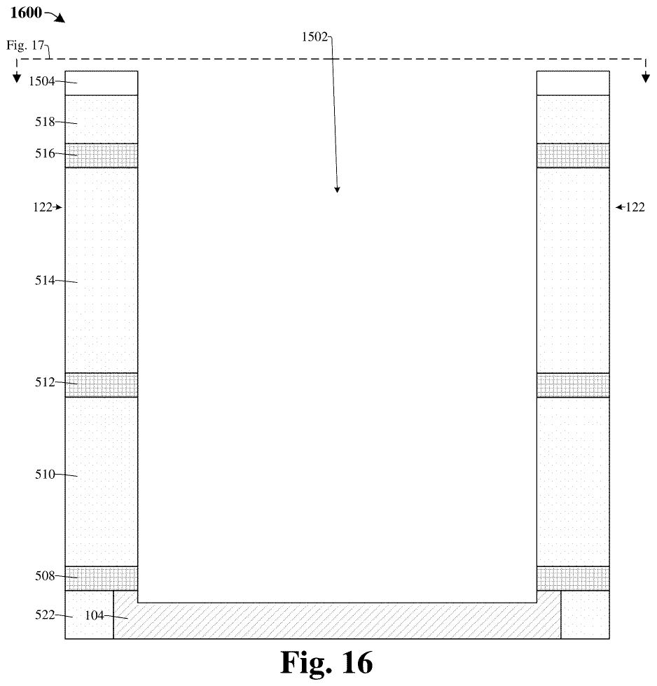

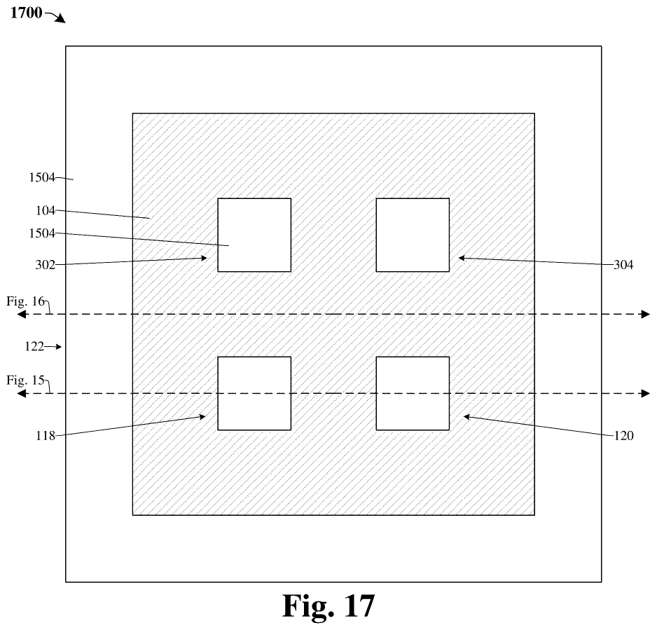

As shown in cross-sectional view 1500 of FIG. 15, cross-sectional view 1600 of FIG. 16, and top view 1700 of FIG. 17, dielectric layer 518, etch stop layer 516, dielectric layer 514, etch stop layer 512, dielectric layer 510, and etch stop layer 508 (e.g., the dielectric stack) are etched to form a grid-shaped trench 1502 therein. The etching forms dielectric pillar structures 118, 120, 302, 304 and an outer dielectric structure 122 from dielectric layer 518, etch stop layer 516, dielectric layer 514, etch stop layer 512, dielectric layer 510, and etch stop layer 508. The grid-shaped trench 1502 is delimited by sidewalls of the dielectric pillars 118, 120, 302, 304, sidewalls of the outer dielectric structure 122, and an upper surface of conductive interconnect 104. The grid-shaped trench 1502 surrounds and extends between the dielectric pillars. The dielectric pillars 118, 120, 302, 304 are on conductive interconnect 104. For example, dielectric pillar 118 is on a first portion of conductive interconnect 104, dielectric pillar 120 is on a second portion of conductive interconnect 104, and so on.

In some embodiments, a masking layer 1504 is formed over dielectric layer 518, and the etching is performed according to the masking layer 1504. In some embodiments, the masking layer 1504 is a photoresist masking layer, a hard masking layer, or some other suitable masking layer. In some embodiments, the etching comprises a dry etching process such as, for example, a plasma etching process, a reactive ion etching process, an ion beam etching process, or some other suitable process. In some embodiments, the etching comprises performing a first etching process to etch stop layer 508, and performing a second etching process to remove portions of etch stop layer 508 and uncover portions of conductive interconnect 104.

In some embodiments, the etching extends slightly into conductive interconnect 104, as illustrated in FIG. 15 and FIG. 16. In some embodiments, the etching extends deeper at the “intersections” of the “streets” of the grid shaped trench 1502 than between the “intersections” (e.g., as illustrated in FIG. 11 and FIG. 12).

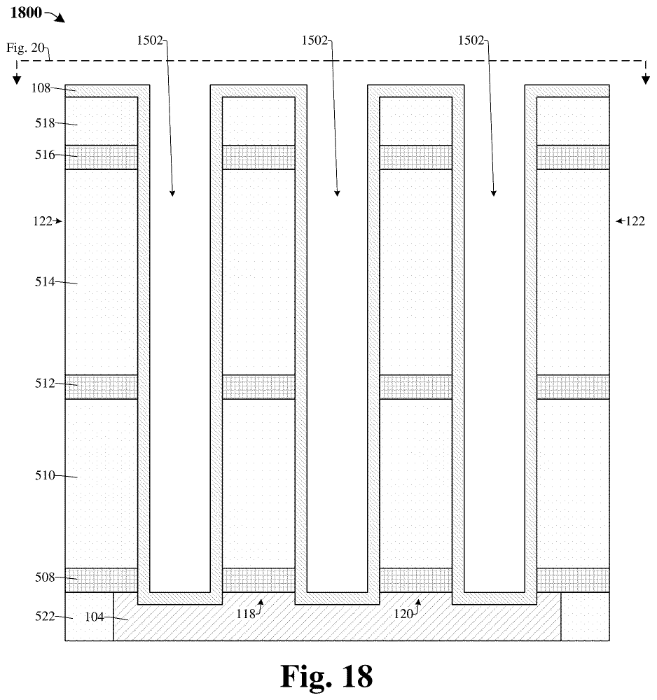

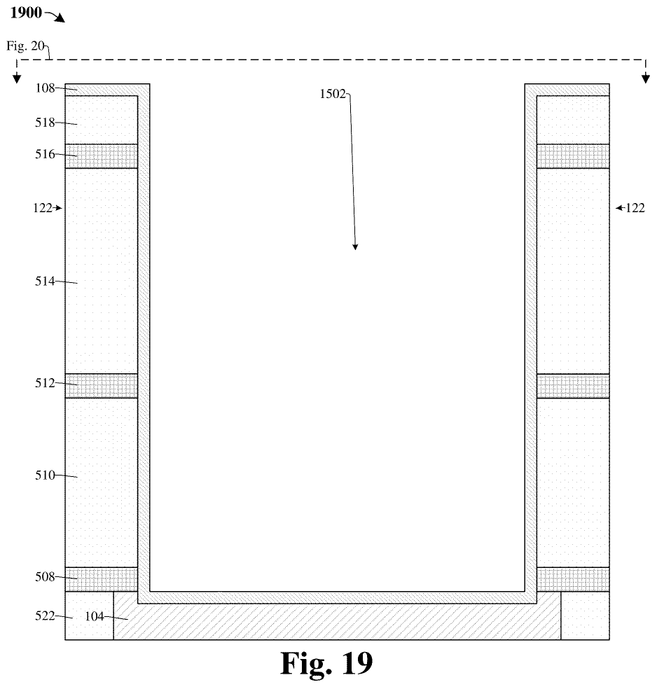

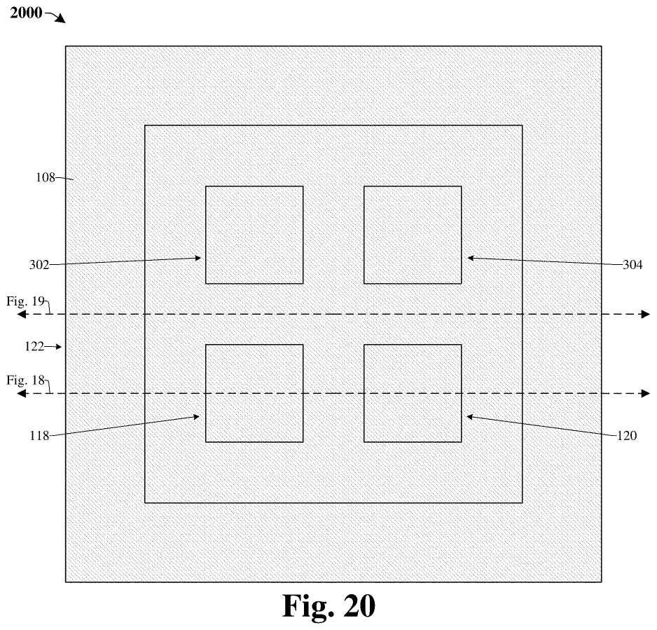

As shown in cross-sectional view 1800 of FIG. 18, cross-sectional view 1900 of FIG. 19, and top view 2000 of FIG. 20, a first conductive layer 108 is deposited in the grid-shaped trench 1502. For example, the first conductive layer 108 is deposited on sidewalls of dielectric layers 518, 514, 510, sidewalls of etch stop layers 516, 512, 508, and a top surface of dielectric layer 518 (e.g., on tops of dielectric pillars 118, 120, 302, 304). Further, the first conductive layer 108 is deposited on conductive interconnect 104. For example, the first conductive layer 108 is deposited on a portion of conductive interconnect 104 which surrounds the portions of conductive interconnect 104 on which the dielectric pillars 118, 120, 302, 304 are disposed.

In some embodiments, the first conductive layer 108 comprises titanium nitride, tantalum, tantalum nitride, a combination of the foregoing, or some other suitable material and is deposited by a chemical vapor deposition (CVD) process, a physical vapor deposition (PVD) process, an atomic layer deposition (ALD) process, or some other suitable process.

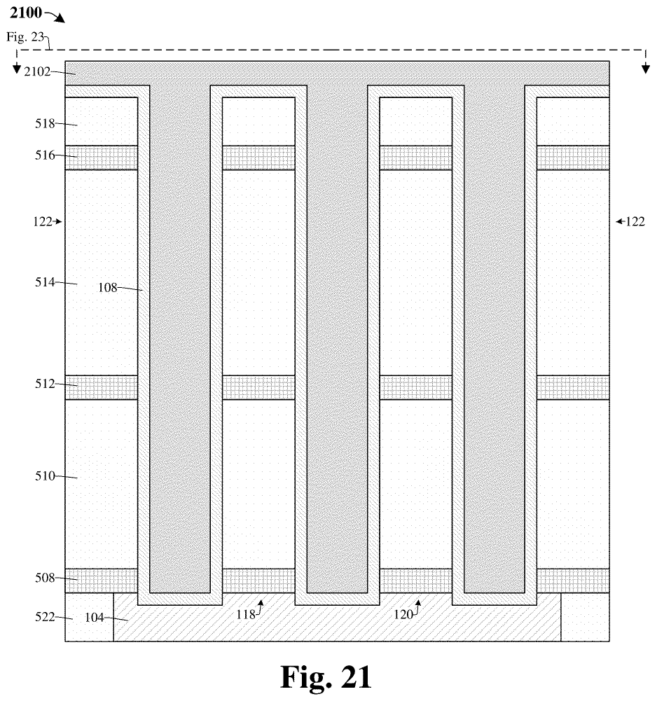

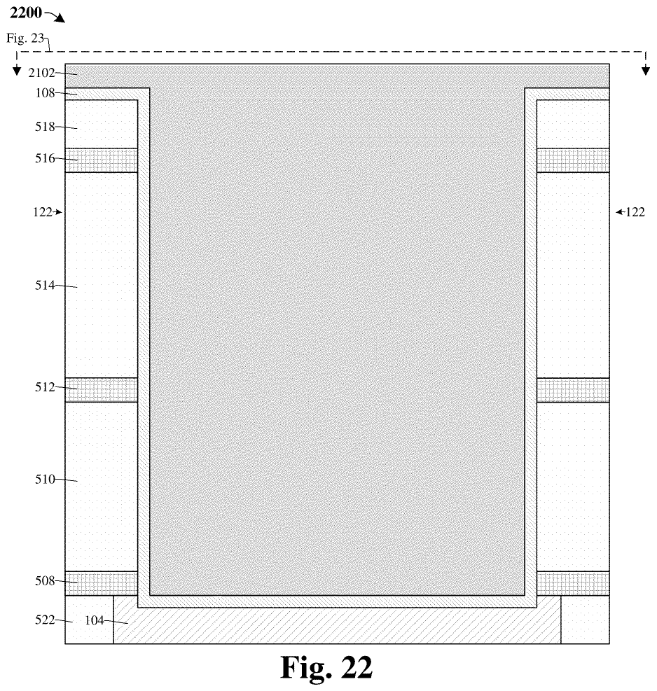

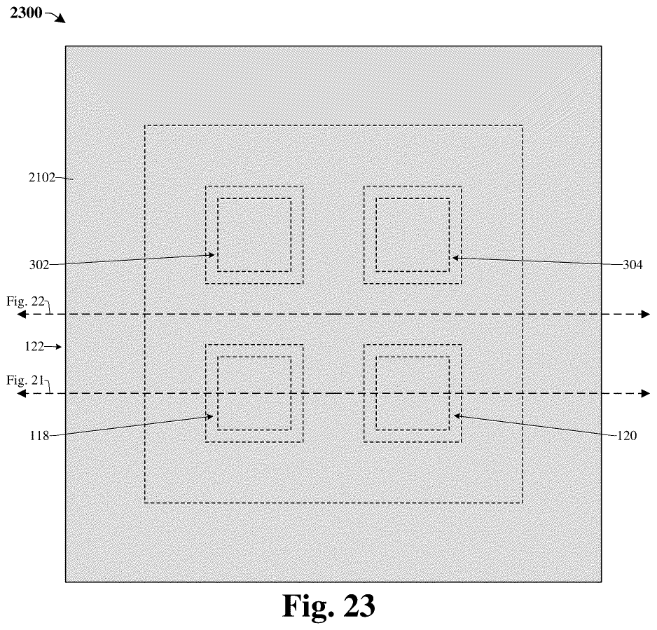

As shown in cross-sectional view 2100 of FIG. 21, cross-sectional view 2200 of FIG. 22, and top view 2300 of FIG. 23, a masking layer 2102 is formed over the first conductive layer 108 and in the trench 1502. In some embodiments, the masking layer 2102 comprises photoresist or some other suitable material and is formed using a spin on process or some other suitable process.

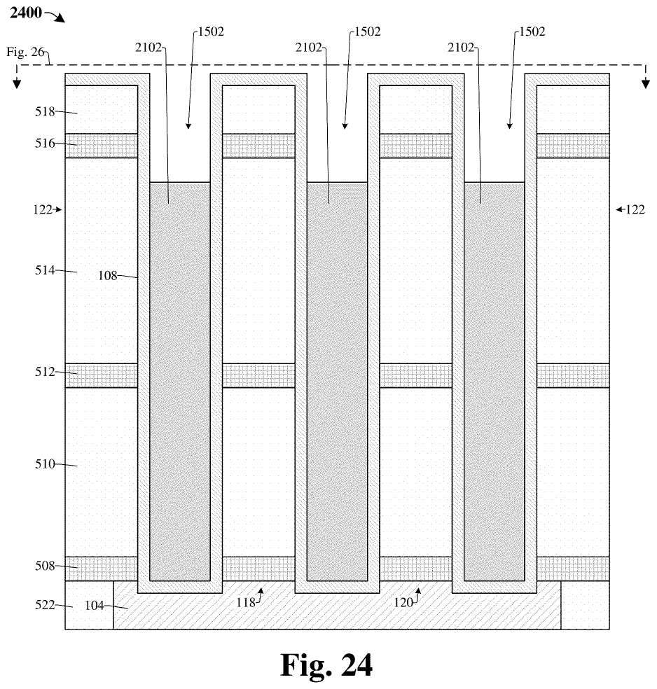

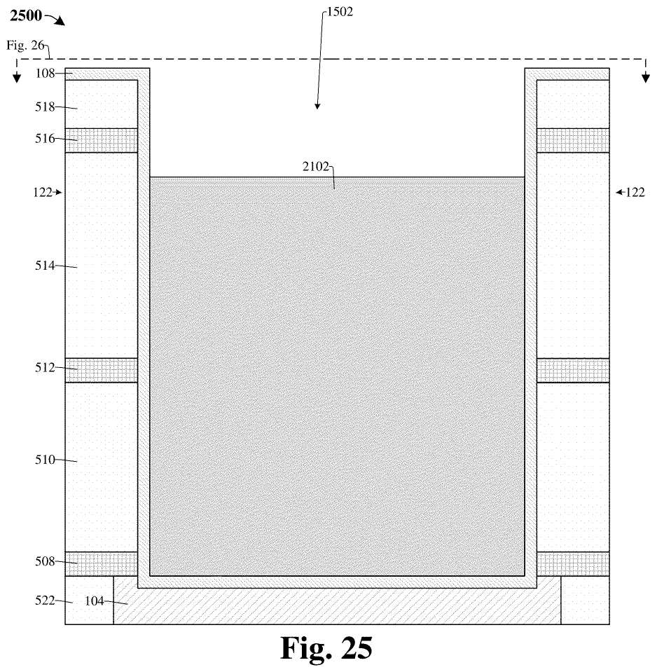

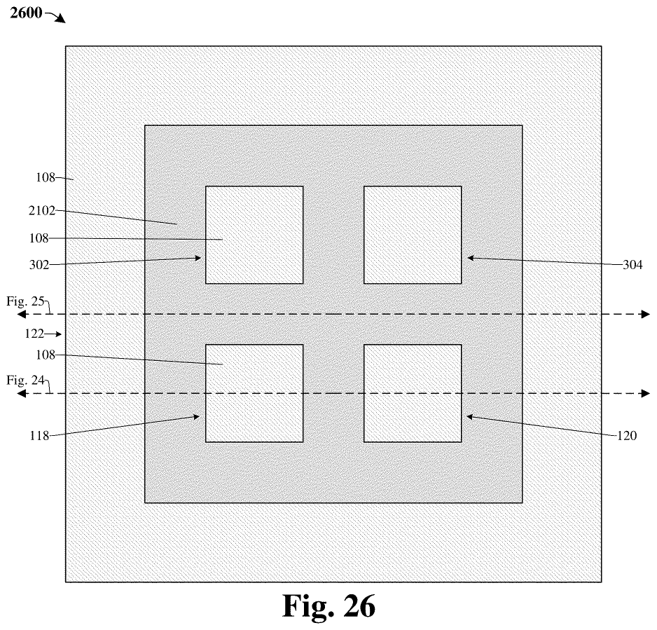

As shown in cross-sectional view 2400 of FIG. 24, cross-sectional view 2500 of FIG. 25, and top view 2600 of FIG. 26, masking layer 2102 is etched to recess masking layer 2102 (e.g., remove an upper portion of masking layer 2102) to below the tops of the dielectric pillars 118, 120, 302, 304 and the tops of conductive layer 108. In some embodiments, the etching comprises a dry etching process, a wet etching process, or some other suitable process.

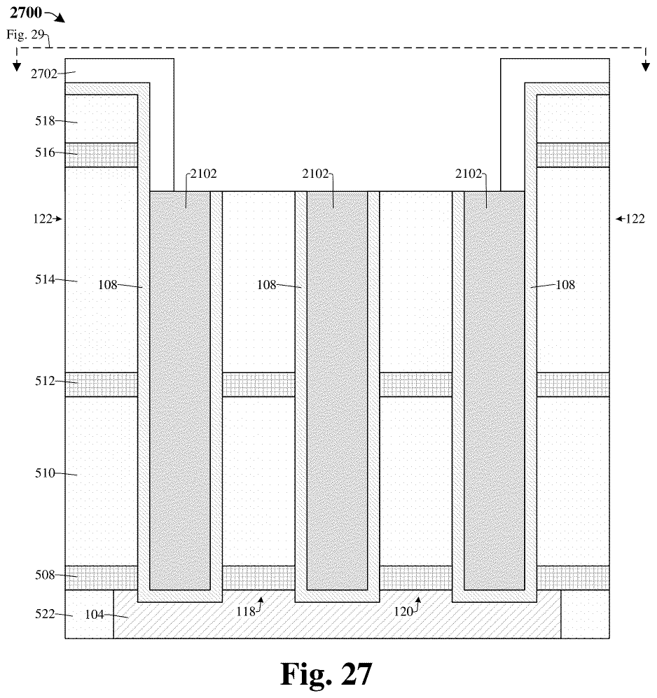

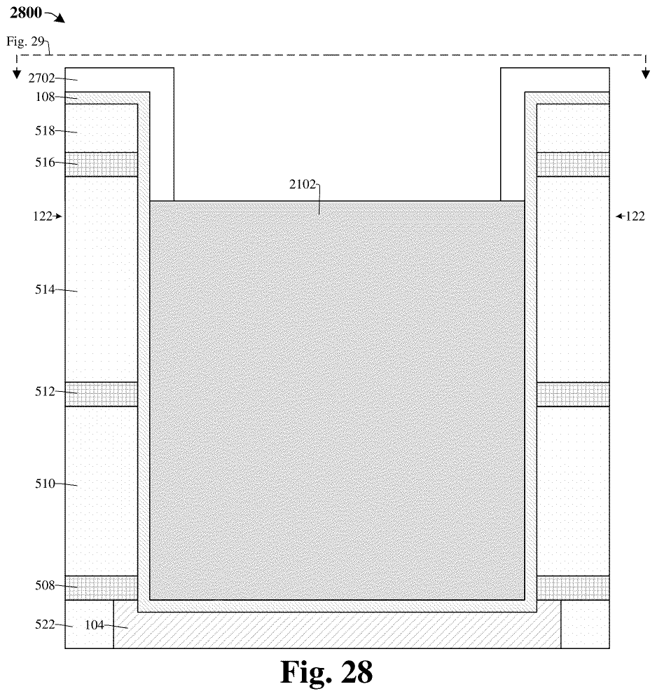

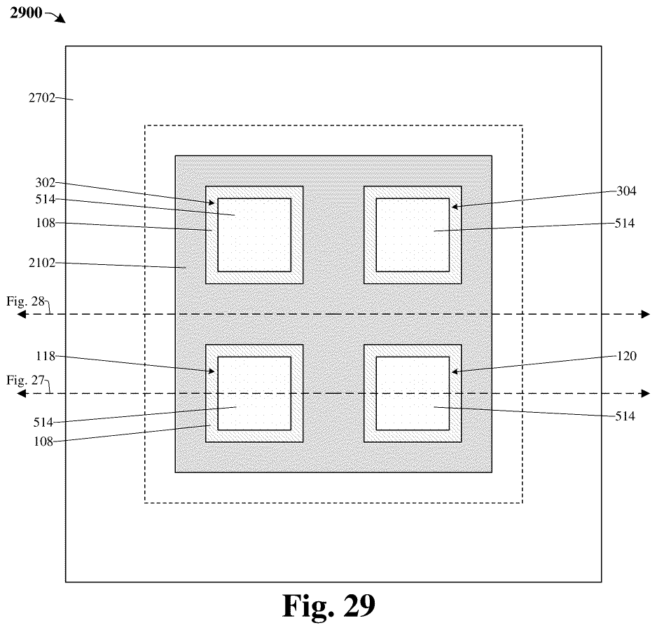

As shown in cross-sectional view 2700 of FIG. 27, cross-sectional view 2800 of FIG. 28, and top view 2900 of FIG. 29, the dielectric pillar structures 118, 120, 302, 304 and portions of the first conductive layer 108 covering the tops of the dielectric pillars 118, 120, 302, 304 are etched to remove the first conductive layer 108 from the tops of the dielectric pillars 118, 120, 302, 304 and to recess (e.g., remove upper portions of) the dielectric pillars 118, 120, 302, 304.

In some embodiments, a masking layer 2702 is formed over the first conductive layer 108 and over a portion of masking layer 2102 along a boundary of trench 1502, and the etching is performed according to the masking layer 2702. In some embodiments, the etching comprises a dry etching process or some other suitable process.

In some embodiments, the depth to which masking layer 2102 is recessed (e.g., as illustrated in FIGS. 24-26) can dictate the amount in which the dielectric pillars 118, 120, 302, 304 are recessed. For example, in some embodiments (e.g., as illustrated in FIGS. 27-29), a top of masking layer 2102 is below a top of dielectric layer 514. Consequently, the etching removes dielectric layer 518, etch stop layer 516, and a portion of dielectric layer 514 from the dielectric pillars 118, 120, 302, 304. In some other embodiments (e.g., corresponding to FIG. 10), the top of masking layer 2102 is just below the top of dielectric layer 518. Consequently, the etching removes a portion of dielectric layer 518 but not etch stop layer 516.

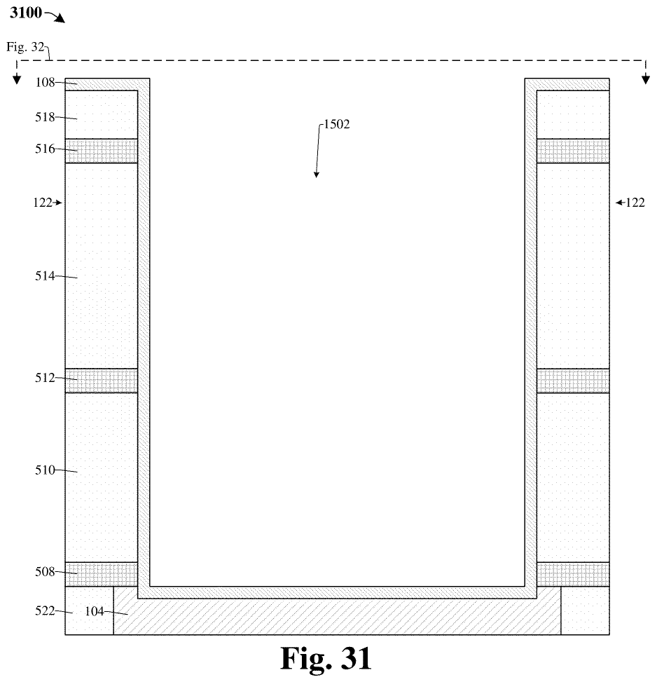

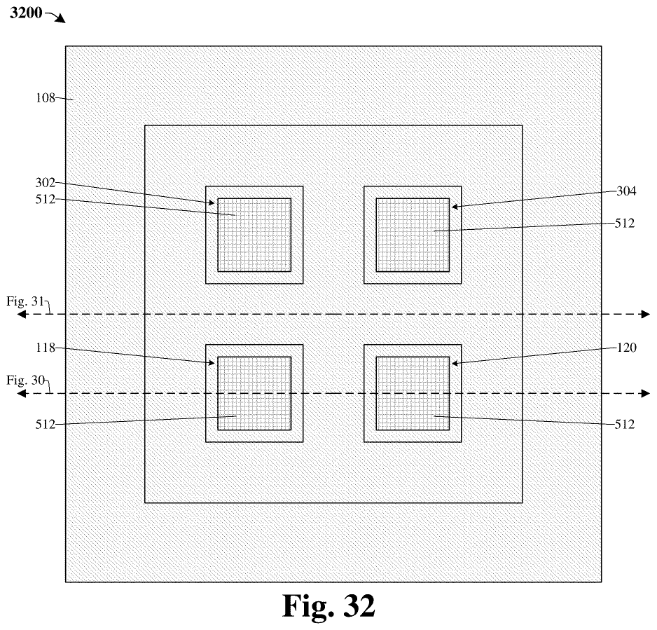

As shown in cross-sectional view 3000 of FIG. 30, cross-sectional view 3100 of FIG. 31, and top view 3200 of FIG. 32, the dielectric pillar structures 118, 120, 302, 304 are etched to further recess the dielectric pillars between sidewalls of the first conductive layer 108. The etching forms recesses 3002 over the dielectric pillars and between sidewalls of the first conductive layer 108. In some embodiments, the etching comprises a wet etching process such as, for example, a hydrofluoric acid wet etching process or some other suitable process. In some embodiments, the etching is performed without a masking layer in place.

Because the first conductive layer 108 covers sidewalls of the outer dielectric structure 122 that delimit a perimeter of trench 1502 (e.g., sidewalls 518a, 518b of dielectric layer 518, sidewalls 516a, 516b of etch stop layer 516, sidewalls 514a, 514b of dielectric layer 518, sidewalls 512a, 512b of etch stop layer 512, sidewalls 510a, 510b of dielectric layer 510, and sidewalls 508a, 508b of etch stop layer 508), the first conductive layer 108 can protect the outer dielectric structure 122 during the etching. Thus, a likelihood of the outer dielectric structure 122 being damaged during the etching can be reduced and hence a reliability of the integrated chip can be improved.

Further, because the portions of the first conductive layer 108 that are “freestanding” above the tops of the dielectric pillars (e.g., portion 3004 and portion 3006 of conductive layer 108) are continuously connected to the rest of conductive layer 108, these “freestanding” portions of conductive layer 108 may have improved structural integrity and may be less susceptible to damage or collapse during fabrication. Thus, a reliability of the integrated chip can be further improved.

In some embodiments (e.g., corresponding to FIG. 5), the etching removes dielectric layer 514 and stops on etch stop layer 512. In some other embodiments (e.g., as illustrated in FIGS. 30-32), the etching further removes a portion of etch stop layer 512. In some other embodiments (e.g., corresponding to FIG. 8), the etching removes etch stop layer 512 and stops on dielectric layer 510. In some embodiments (e.g., corresponding to FIG. 9) the etching removes dielectric layer 510 and stops on etch stop layer 508.

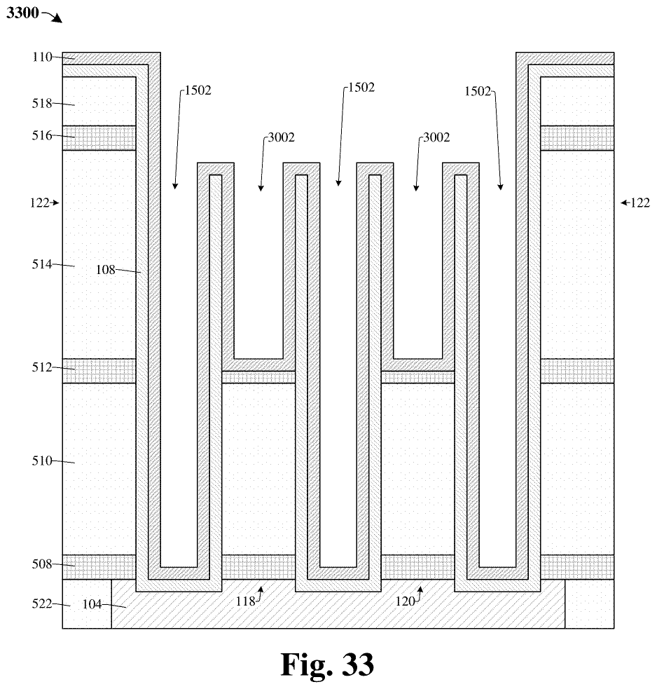

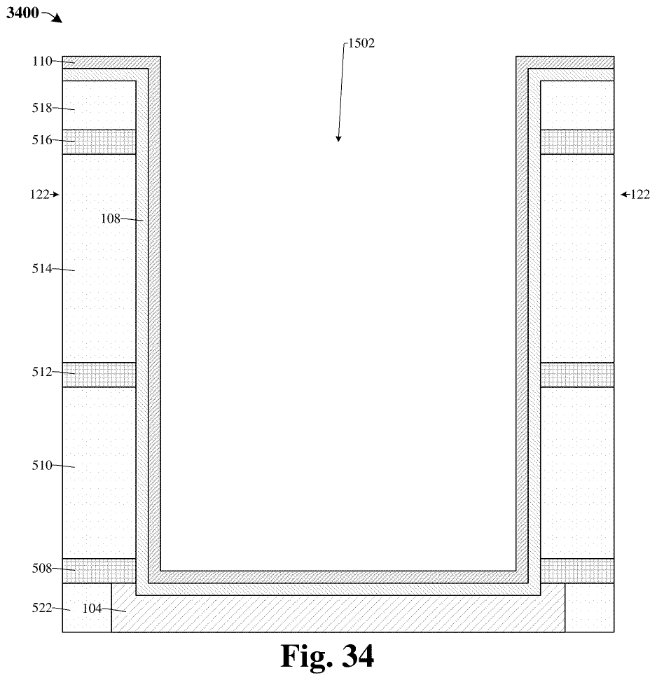

As shown in cross-sectional view 3300 of FIG. 33 and cross-sectional view 3400 of FIG. 34, a second conductive layer 110 is conformally deposited on the first conductive layer 108. For example, the second conductive layer 110 is deposited on sidewalls and upper surfaces of the first conductive layer 108. The second conductive layer 110 is also deposited on top surfaces of the dielectric pillars 118, 120, 302, 304. In some embodiments, the second conductive layer 110 comprises a different conductor than the first conductive layer 108. In some embodiments, the second conductive layer 110 comprises titanium nitride or some other suitable material and is deposited by a CVD process, a PVD process, an ALD process, or some other suitable process. In some embodiments, the deposition of the second conductive layer 110 is skipped (e.g., corresponding to FIG. 7).

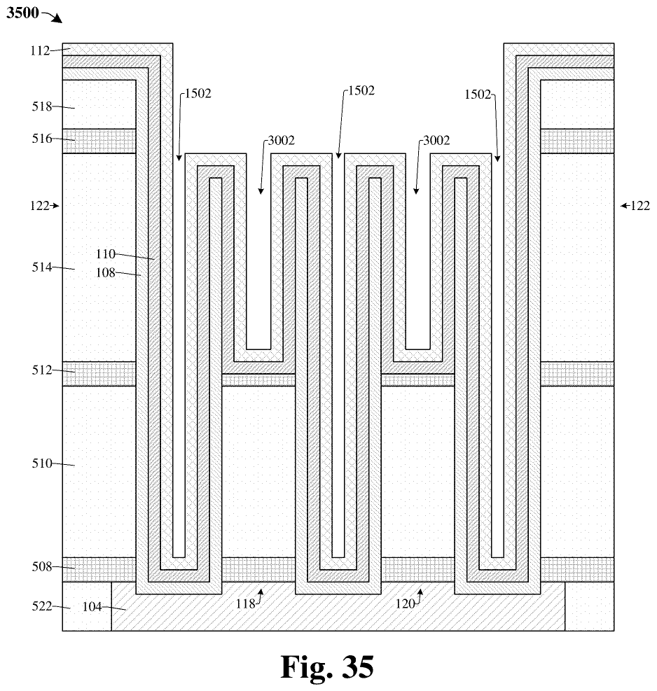

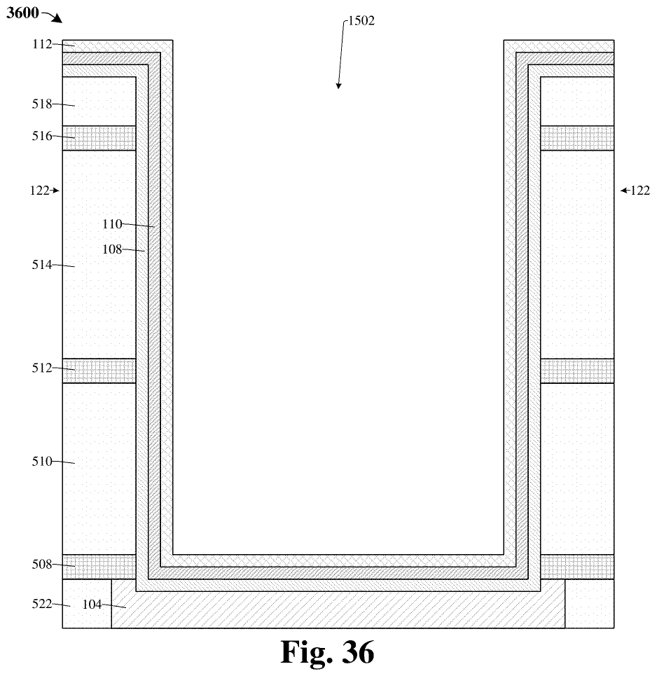

As shown in cross-sectional view 3500 of FIG. 35 and cross-sectional view 3600 of FIG. 36, an insulator layer 112 is conformally deposited on the second conductive layer 110. In some embodiments, the insulator layer 112 comprises a high k dielectric such as, for example, hafnium oxide, tantalum oxide, aluminum oxide, or some other suitable material and is deposited by a CVD process, a PVD process, an ALD process, or some other suitable process.

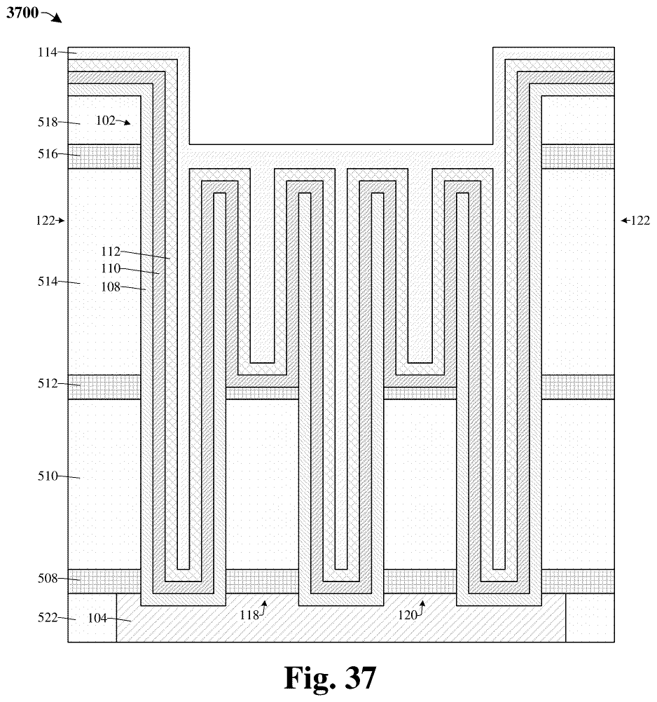

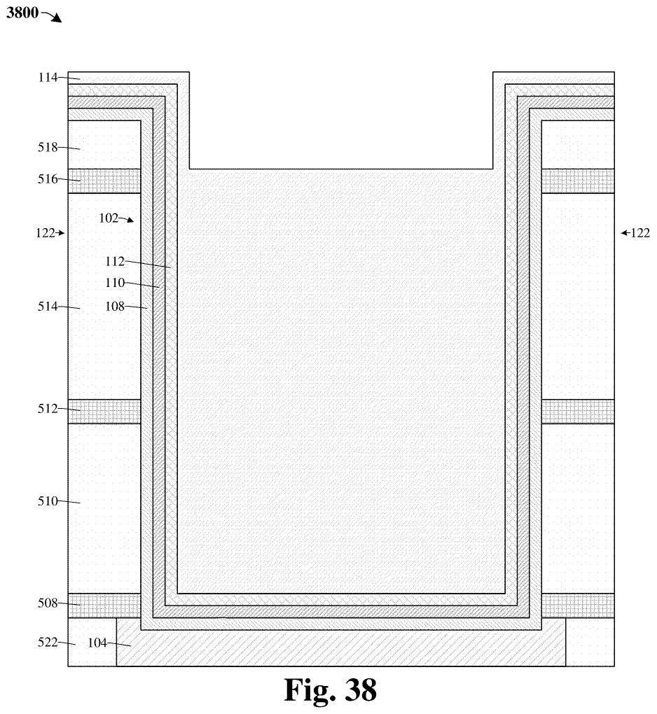

As shown in cross-sectional view 3700 of FIG. 37 and cross-sectional view 3800 of FIG. 38, a third conductive layer 114 is conformally deposited on the insulator layer 112 and fills (at least partially) a remainder of the grid-shaped trench 1502. In some embodiments, the third conductive layer 114 comprises titanium nitride or some other suitable material and is deposited by a CVD process, a PVD process, an ALD process, or some other suitable process.

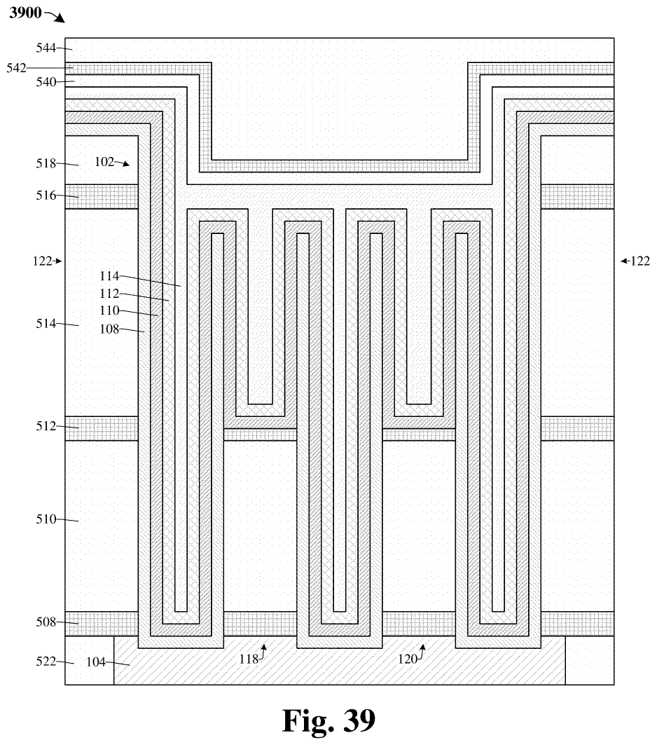

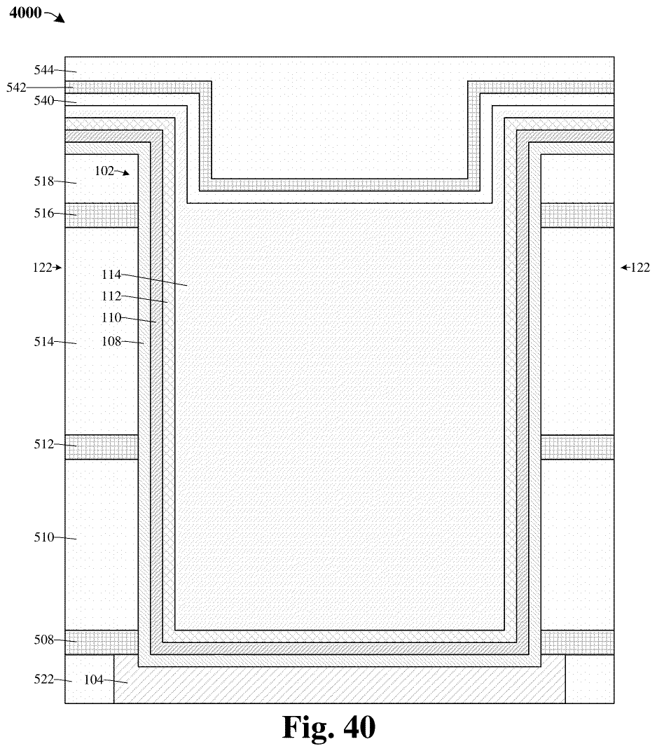

As shown in cross-sectional view 3900 of FIG. 39 and cross-sectional view 4000 of FIG. 40, a dielectric layer 540 is conformally deposited on the third conductive layer 114. An etch stop layer 542 is conformally deposited on dielectric layer 540. A dielectric layer 544 is deposited over etch stop layer 542. A planarization process is performed on dielectric layer 544.

In some embodiments, dielectric layers 540, 544 comprise silicon oxide or some other suitable material and are deposited by a CVD process, a PVD process, an ALD process, or some other suitable process. In some embodiments, etch stop layer 542 comprises silicon nitride or some other suitable material and is deposited by a CVD process, a PVD process, an ALD process, or some other suitable process. In some embodiments, the planarization process comprises a chemical mechanical planarization (CMP) or some other suitable process.

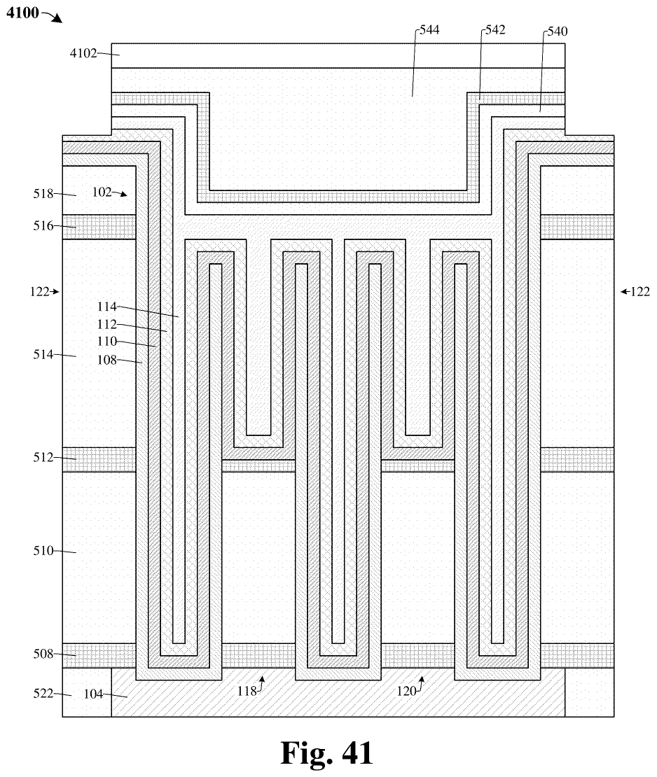

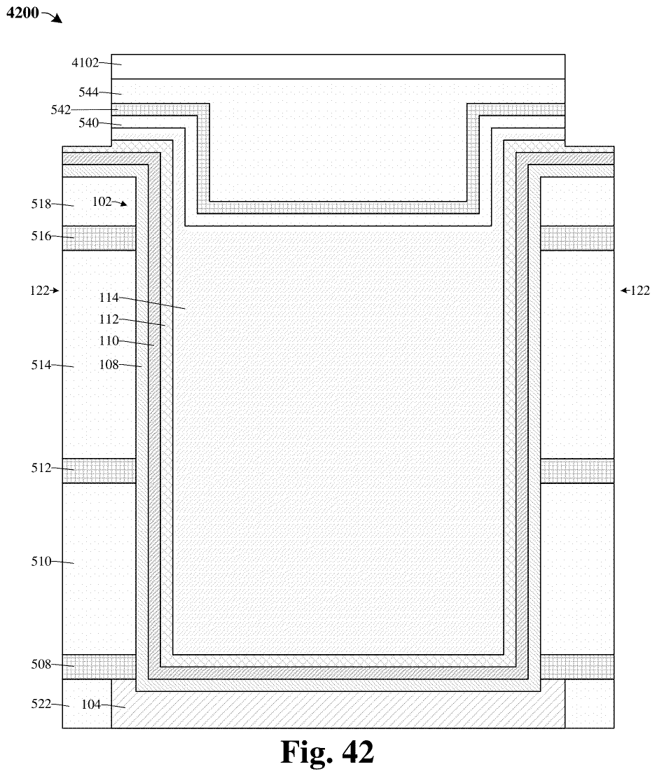

As shown in cross-sectional view 4100 of FIG. 41 and cross-sectional view 4200 of FIG. 42, dielectric layer 544, etch stop layer 542, dielectric layer 540, and the third conductive layer 114 are etched to delimit the third conductive layer 114 (e.g., to delimit the top electrode of the capacitor 102). In some embodiments, the etching stops at the insulator layer 112. In some other embodiments, the etching extends into and removes a portion of the insulator layer 112. In some embodiments, a masking layer 4102 is formed over dielectric layer 544, and the etching is performed according to the masking layer 4102. In some embodiments, the etching comprises a dry etching process or some other suitable process.

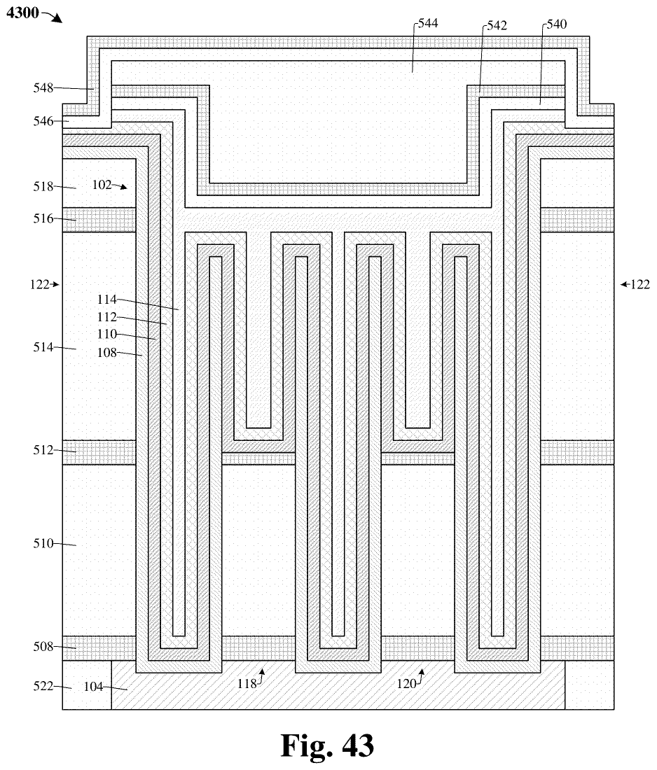

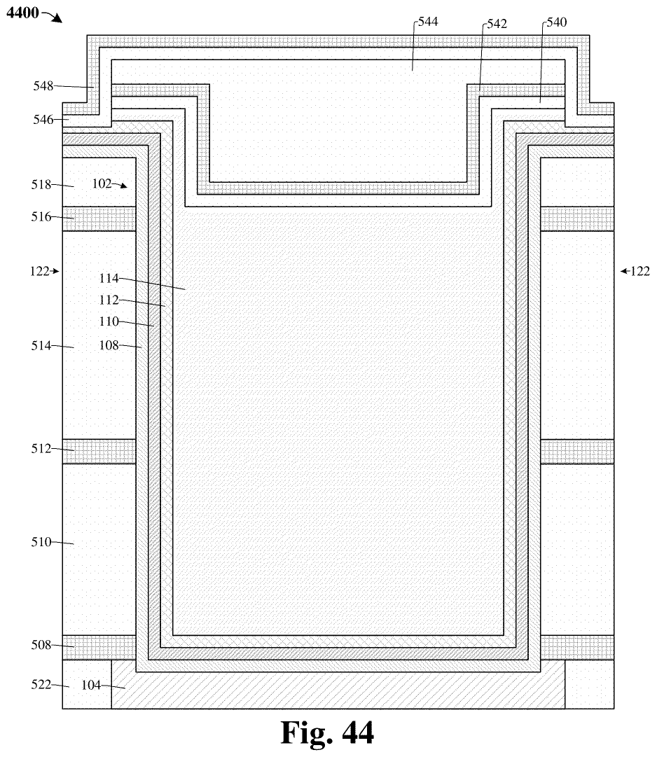

As shown in cross-sectional view 4300 of FIG. 43 and cross-sectional view 4400 of FIG. 44, a dielectric layer 546 is conformally deposited over dielectric layer 544, along sidewalls of dielectric layer 544, along sidewalls of etch stop layer 542, along sidewalls of dielectric layer 540, along sidewalls of conductive layer 114, and over insulator layer 112. Further, an etch stop layer 548 is conformally deposited on dielectric layer 546.

In some embodiments, dielectric layer 546 comprises silicon oxide or some other suitable material and is deposited by a CVD process, a PVD process, an ALD process, or some other suitable process. In some embodiments, etch stop layer 548 comprises silicon nitride or some other suitable material and is deposited by a CVD process, a PVD process, an ALD process, or some other suitable process.

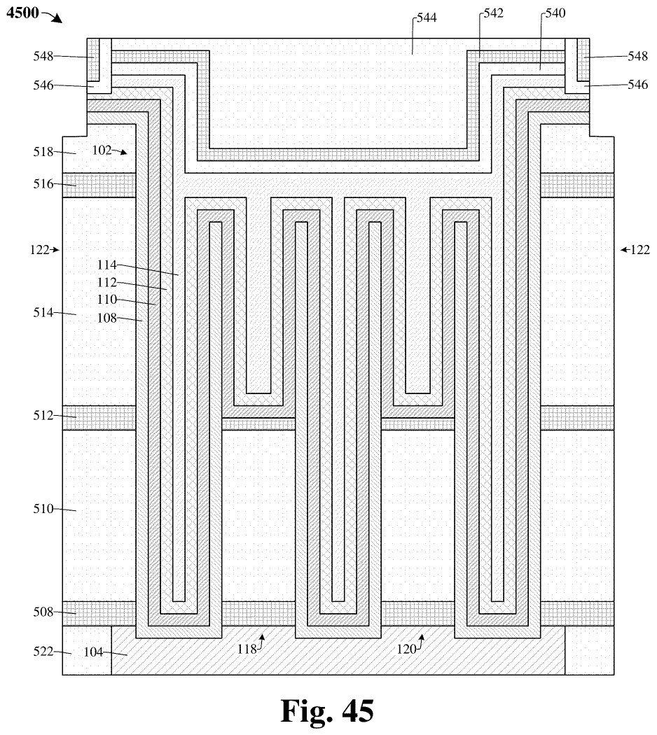

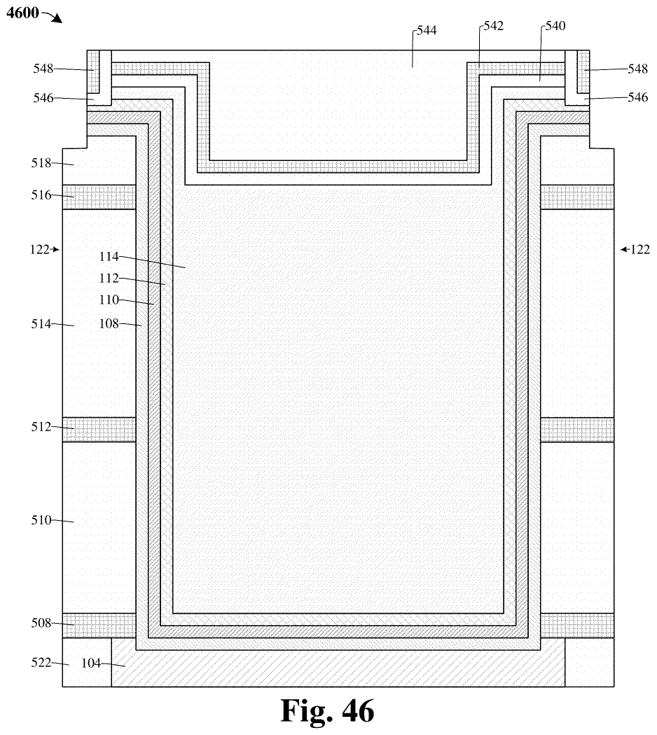

As shown in cross-sectional view 4500 of FIG. 45 and cross-sectional view 4600 of FIG. 46, a “self-aligned” etching process is performed on the insulator layer 112, the second conductive layer 110, and the first conductive layer 108 to further delimit the insulator layer 112, the second conductive layer 110, and the first conductive layer 108 (e.g., to delimit the insulator and the first electrode of the capacitor 102). For example, a blanket etching process (e.g., a mask-less etching process) is performed which removes dielectric layer 546 and etch stop layer 548 from over dielectric layer 544 and insulator layer 112. In some embodiments, the blanket etching extends slightly into dielectric layer 544 and dielectric layer 518. A portion of dielectric layer 546 and a portion of etch stop layer 548 remain along sidewalls of dielectric layer 544, along sidewalls of etch stop layer 542, along sidewalls of dielectric layer 546, along sidewalls of the third conductive layer 114, and over the insulator layer 112. In some embodiments, the blanket etching process comprises a dry etching process or some other suitable material.

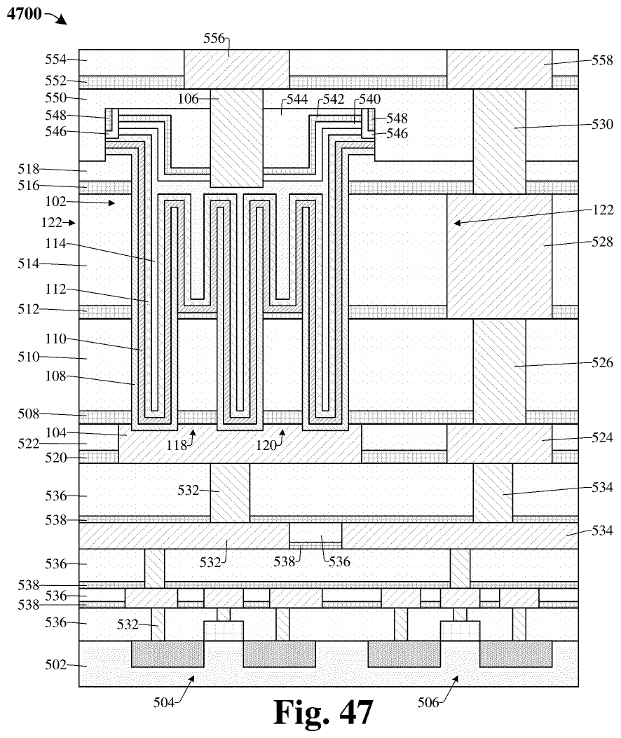

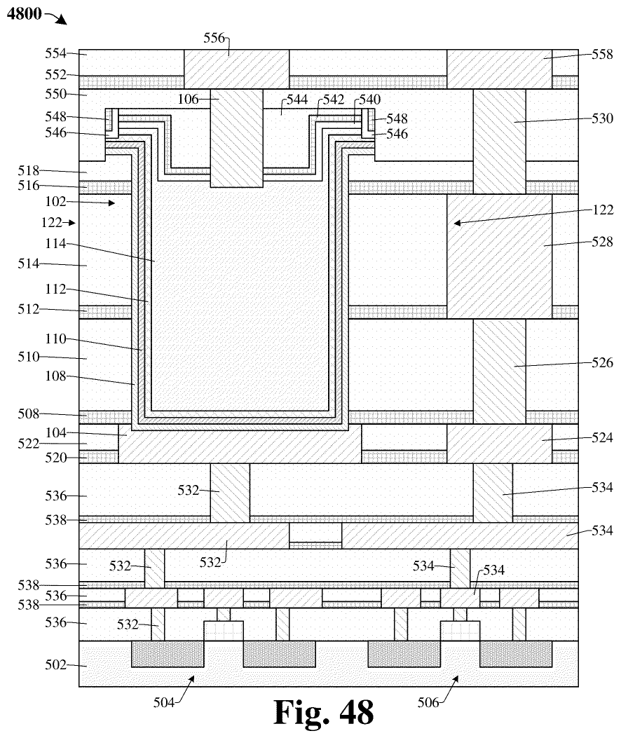

As shown in cross-sectional view 4700 of FIG. 47 and cross-sectional view 4800 of FIG. 48, a dielectric layer 550 is deposited over the capacitor 102 (e.g., over dielectric layer 544) and conductive interconnect 528. An etch stop layer 552 is deposited over dielectric layer 550. A dielectric layer 554 is deposited over etch stop layer 552. Further, a conductive interconnect 106 (e.g., a conductive via) is formed on the third conductive layer 114 of the capacitor 102 (e.g., the second electrode of the capacitor 102). A conductive interconnect 530 (e.g., a conductive line) is formed on conductive interconnect 528. A conductive interconnect 556 is formed on conductive interconnect 106. A conductive interconnect 558 is formed on conductive interconnect 530.

In some embodiments, dielectric layers 550, 554 comprises silicon oxide or some other suitable material and is deposited by a CVD process, a PVD process, an ALD process, or some other suitable process. In some embodiments, etch stop layer 552 comprises silicon nitride or some other suitable material and is deposited by a CVD process, a PVD process, an ALD process, or some other suitable process.

In some embodiments, conductive interconnect 106 is formed by uncovering a portion of the third conductive layer 114 with an etching process, and depositing copper, tungsten, aluminum, or some other suitable material on the portion of the third conductive layer 114 by a CVD process, a PVD process, an ALD process, or some other suitable process. In some embodiments, the etching extends slightly into the third conductive layer 114 and thus conductive interconnect 106 extends slightly into the third conductive layer 114. In some embodiments, conductive interconnects 556, 530, 558 comprise copper, tungsten, aluminum, or some other suitable material and are deposited by CVD, PVD, ALD, or some other suitable process.

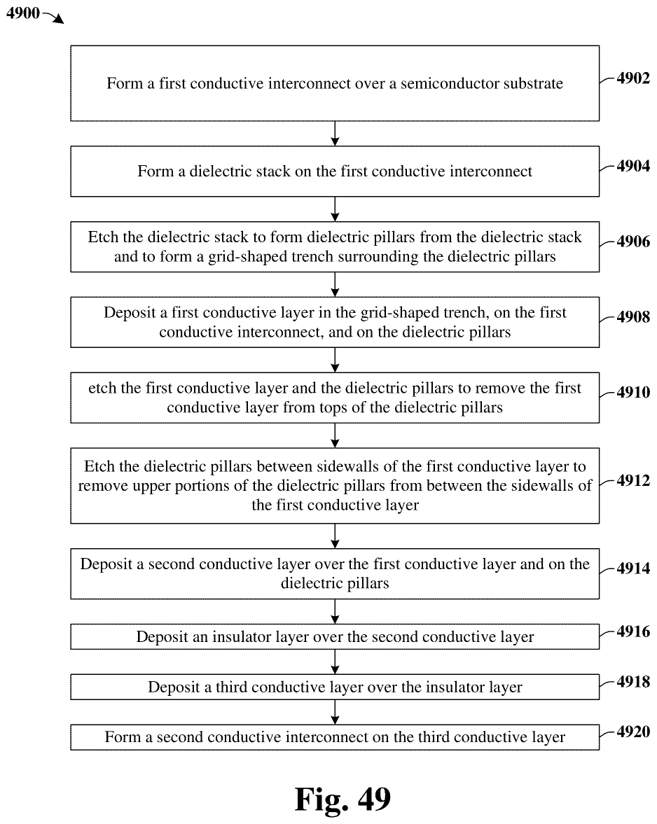

FIG. 49 illustrates a flow diagram of some embodiments of a method 4900 of forming an integrated chip including a three-dimensional capacitor. While method 4900 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 4902, form a first conductive interconnect over a semiconductor substrate. FIG. 14 illustrates a cross-sectional view 1400 of some embodiments corresponding to block 4902.

At block 4904, form a dielectric stack on the first conductive interconnect. FIG. 14 illustrates a cross-sectional view 1400 of some embodiments corresponding to block 4904.

At block 4906, etch the dielectric stack to form dielectric pillars from the dielectric stack and to form a grid-shaped trench surrounding the dielectric pillars. FIG. 15 illustrates a cross-sectional view 1500, FIG. 16 illustrates a cross-sectional view 1600, and FIG. 17 illustrates a top view 1700 of some embodiments corresponding to block 4906.

At block 4908, deposit a first conductive layer in the grid-shaped trench, on the first conductive interconnect, and on the dielectric pillars. FIG. 18 illustrates a cross-sectional view 1800, FIG. 19 illustrates a cross-sectional view 1900, and FIG. 20 illustrates a top view 2000 of some embodiments corresponding to block 4908.

At block 4910, etch the first conductive layer and the dielectric pillars to remove the first conductive layer from tops of the dielectric pillars. FIG. 27 illustrates a cross-sectional view 2700, FIG. 28 illustrates a cross-sectional view 2800, and FIG. 29 illustrates a top view 2900 of some embodiments corresponding to block 4910.

At block 4912, etch the dielectric pillars between sidewalls of the first conductive layer to remove upper portions of the dielectric pillars from between the sidewalls of the first conductive layer. FIG. 30 illustrates a cross-sectional view 3000, FIG. 31 illustrates a cross-sectional view 3100, and FIG. 32 illustrates a top view 3200 of some embodiments corresponding to block 4912.

At block 4914, deposit a second conductive layer over the first conductive layer and on the dielectric pillars. FIG. 33 illustrates a cross-sectional view 3300 and FIG. 34 illustrates a cross-sectional view 3400 of some embodiments corresponding to block 4914.

At block 4916, deposit an insulator layer over the second conductive layer. FIG. 35 illustrates a cross-sectional view 3500 and FIG. 36 illustrates a cross-sectional view 3600 of some embodiments corresponding to block 4916.

At block 4918, deposit a third conductive layer over the insulator layer. FIG. 37 illustrates a cross-sectional view 3700 and FIG. 38 illustrates a cross-sectional view 3800 of some embodiments corresponding to block 4918.

At block 4920, form a second conductive interconnect on the third conductive layer. FIG. 47 illustrates a cross-sectional view 4700 and FIG. 48 illustrates a cross-sectional view 4800 of some embodiments corresponding to block 4920.

Thus, the present disclosure relates to an integrated chip and a method of forming an integrated chip comprising a three-dimensional capacitor having a grid-shaped layout.

Accordingly, in some embodiments, the present disclosure relates to a method of forming an integrated chip. The method includes forming a first conductive interconnect over a semiconductor substrate. The method includes forming a dielectric stack on the first conductive interconnect. The method includes etching the dielectric stack to uncover a first portion of the first conductive interconnect and form a first dielectric pillar structure from the dielectric stack. The first dielectric pillar structure is on a second portion of the first conductive interconnect. The first portion of the first conductive interconnect surrounds the second portion of the first conductive interconnect. The method includes depositing a first conductive layer on the first portion of the first conductive interconnect, a first sidewall of the first dielectric pillar structure, a second sidewall of the first dielectric pillar structure, and a first top surface of the first dielectric pillar structure. The method includes etching the first conductive layer and the first dielectric pillar structure to remove the first conductive layer from the first top surface of the first dielectric pillar structure. The method includes etching the first dielectric pillar structure between a first sidewall and a second sidewall of the first conductive layer to remove an upper portion of the first dielectric pillar structure from between the first and second sidewalls of the first conductive layer. The method includes depositing an insulator layer over the first conductive layer and the first dielectric pillar structure and surrounding the first dielectric pillar structure. The method includes depositing a second conductive layer over the insulator layer and the first dielectric pillar structure and surrounding the first dielectric pillar structure. The method includes forming a second conductive interconnect over and coupled to the second conductive layer.

In other embodiments, the present disclosure relates to a method of forming an integrated chip. The method includes forming a first conductive interconnect over a semiconductor substrate. The method includes forming a first dielectric pillar structure on the first conductive interconnect. The method includes forming a first conductive layer on the first conductive interconnect and beside the first dielectric pillar structure. The method includes forming an insulator layer over the first conductive layer and the first dielectric pillar structure. The method includes forming a second conductive layer over the insulator layer and the first dielectric pillar structure. The method includes forming a second conductive interconnect on the second conductive layer. The first conductive layer, the insulator layer, and the second conductive layer laterally surround the first dielectric pillar structure along sidewalls of the first dielectric pillar structure. The insulator layer and the second conductive layer cover a top surface of the first dielectric pillar structure.

In yet other embodiments, the present disclosure relates to an integrated chip. The integrated chip includes a semiconductor substrate. The integrated chip includes a first conductive interconnect over the semiconductor substrate. The integrated chip includes a first dielectric pillar structure on the first conductive interconnect. The integrated chip includes a first conductive layer beside the first dielectric pillar structure and extending from the first conductive interconnect to above the first dielectric pillar structure. The integrated chip includes an insulator layer over the first conductive layer and the first dielectric pillar structure. The integrated chip includes a second conductive layer over the insulator layer and the first dielectric pillar structure. The integrated chip includes a second conductive interconnect on the second conductive layer. The first conductive layer, the insulator layer, and the second conductive layer laterally surround the first dielectric pillar structure along sidewalls of the first dielectric pillar structure. The insulator layer and the second conductive layer cover a top surface of the first dielectric pillar structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming an integrated chip, the method comprising:
forming a first conductive interconnect over a semiconductor substrate;
forming a dielectric stack on the first conductive interconnect;
etching the dielectric stack to uncover a first portion of the first conductive interconnect and form a first dielectric structure from the dielectric stack, wherein the first dielectric structure is on a second portion of the first conductive interconnect, and wherein the first portion of the first conductive interconnect surrounds the second portion of the first conductive interconnect;
depositing a first conductive layer on the first portion of the first conductive interconnect, a first sidewall of the first dielectric structure, a second sidewall of the first dielectric structure, and a first top surface of the first dielectric structure;
etching the first conductive layer and the first dielectric structure to remove the first conductive layer from the first top surface of the first dielectric structure;
etching the first dielectric structure between a first sidewall and a second sidewall of the first conductive layer to remove an upper portion of the first dielectric structure from between the first and second sidewalls of the first conductive layer;
depositing an insulator layer over the first conductive layer and the first dielectric structure and surrounding the first dielectric structure;
depositing a second conductive layer over the insulator layer and the first dielectric structure and surrounding the first dielectric structure; and
forming a second conductive interconnect over and coupled to the second conductive layer.

2. The method of claim 1, further comprising:
depositing a third conductive layer over the first conductive layer and on a second top surface of the first dielectric structure after removing the upper portion of the first dielectric structure, wherein the insulator layer is deposited over the third conductive layer.

3. The method of claim 1, wherein etching the dielectric stack forms a second dielectric structure from the dielectric stack, wherein the second dielectric structure is on a third portion of the first conductive interconnect, and wherein the first portion of the first conductive interconnect surrounds the third portion of the first conductive interconnect and extends between the second and third portions of the first conductive interconnect.

4. The method of claim 3, further comprising:
depositing the first conductive layer on a first sidewall of the second dielectric structure, a second sidewall of the second dielectric structure, and a first top surface of the second dielectric structure;
etching the first conductive layer and the second dielectric structure to remove the first conductive layer from the first top surface of the second dielectric structure;
etching the second dielectric structure between a third sidewall and a fourth sidewall of the first conductive layer to remove an upper portion of the second dielectric structure from between the third and fourth sidewalls of the first conductive layer; and
depositing the insulator layer and the second conductive layer over the second dielectric structure and surrounding the second dielectric structure.

5. The method of claim 1, further comprising:
forming a first masking layer over the first conductive layer and the first dielectric structure and laterally surrounding the first dielectric structure before etching the first conductive layer and the first dielectric structure; and
etching the first masking layer to remove an upper portion of the first masking layer from over the first dielectric structure, wherein a lower portion of the first masking layer laterally surrounds the first dielectric structure along the first and second sidewalls of the first dielectric structure after etching the first masking layer, and wherein the etching of the first conductive layer and the first dielectric structure is performed according to the first masking layer.

6. The method of claim 5, further comprising:
forming a second masking layer over the first conductive layer and the lower portion of the first masking layer along an outer perimeter of the first masking layer before etching the first conductive layer and the first dielectric structure, wherein the etching of the first conductive layer and the first dielectric structure is performed according to the first masking layer and the second masking layer.

7. The method of claim 6, wherein the etching of the first conductive layer and the first dielectric structure according to the first masking layer and the second masking layer removes a topmost portion of the first dielectric structure before the upper portion of the first dielectric structure is removed from between the first and second sidewalls of the first conductive layer.

8. The method of claim 1, wherein etching the dielectric stack forms a second dielectric structure, a third dielectric structure, a fourth dielectric structure, and an outer dielectric structure from the dielectric stack, wherein the outer dielectric structure laterally surrounds the first dielectric structure, the second dielectric structure, the third dielectric structure, and the fourth dielectric structure, and wherein etching the dielectric stack forms a grid-shaped trench that is delimited by the first dielectric structure, the second dielectric structure, the third dielectric structure, the fourth dielectric structure, and the outer dielectric structure.

9. The method of claim 8, further comprising:
depositing the first conductive layer on sidewalls of the outer dielectric structure, wherein the first conductive layer covers the sidewalls of the outer dielectric structure during the etching of the etching of the first dielectric structure between the first and second sidewalls of the first conductive layer.

10. A method of forming an integrated chip, the method comprising:
forming a first conductive interconnect over a semiconductor substrate;
forming a first dielectric structure on the first conductive interconnect;
forming a first conductive layer on the first conductive interconnect and beside the first dielectric structure;
forming an insulator layer over the first conductive layer and the first dielectric structure;
forming a second conductive layer over the insulator layer and the first dielectric structure; and
forming a second conductive interconnect on the second conductive layer,
wherein the first conductive layer, the insulator layer, and the second conductive layer laterally surround the first dielectric structure along sidewalls of the first dielectric structure, and wherein the insulator layer and the second conductive layer cover a top surface of the first dielectric structure.

11. The method of claim 10, further comprising:
forming a second dielectric structure on the first conductive interconnect and laterally spaced from the first dielectric structure, wherein the first conductive layer, wherein the first conductive layer, the insulator layer, and the second conductive layer laterally surround the second dielectric structure along sidewalls of the second dielectric structure, and wherein the insulator layer and the second conductive layer cover a top surface of the second dielectric structure.

12. The method of claim 10, further comprising:
forming a third conductive layer on the first conductive layer, laterally surrounding the first dielectric structure along the sidewalls of the first dielectric structure, and on the top surface of the first dielectric structure, wherein the insulator layer is formed over the third conductive layer.

13. The method of claim 10, wherein the first dielectric structure is on a first portion of the first conductive interconnect and the first conductive layer is on a second portion of the first conductive interconnect, and wherein the second portion of the first conductive interconnect surrounds the first portion of the first conductive interconnect.

14. The method of claim 10, further comprising:
forming a second dielectric structure on the first conductive interconnect;
forming a third dielectric structure on the first conductive interconnect; and
forming a fourth dielectric structure on the first conductive interconnect,
wherein the wherein the first conductive layer, the insulator layer, and the second conductive layer form a three-dimensional capacitor which surrounds the first dielectric structure, the second dielectric structure, the third dielectric structure, and the fourth dielectric structure in a grid-shaped layout.

15. An integrated chip comprising:
a semiconductor substrate;
a first conductive interconnect over the semiconductor substrate;
a first dielectric structure on the first conductive interconnect;
a first conductive layer beside the first dielectric structure and extending from the first conductive interconnect to above the first dielectric structure;
an insulator layer over the first conductive layer and the first dielectric structure;
a second conductive layer over the insulator layer and the first dielectric structure; and
a second conductive interconnect on the second conductive layer,
wherein the first conductive layer, the insulator layer, and the second conductive layer laterally surround the first dielectric structure along sidewalls of the first dielectric structure, and wherein the insulator layer and the second conductive layer cover a top surface of the first dielectric structure.

16. The integrated chip of claim 15, further comprising:
a second dielectric structure on the first conductive interconnect and laterally spaced from the first dielectric structure, wherein the first conductive layer is beside the second dielectric structure and extends from the first conductive interconnect to above the second dielectric structure, wherein the first conductive layer, the insulator layer, and the second conductive layer laterally surround the second dielectric structure along sidewalls of the second dielectric structure, wherein the first conductive layer, the insulator layer, and the second conductive layer extend between the first and second dielectric structures, and wherein the insulator layer and the second conductive layer cover a top surface of the second dielectric structure.

17. The integrated chip of claim 15, further comprising:
a third conductive layer on the first conductive layer, laterally surrounding the first dielectric structure along the sidewalls of the first dielectric structure, and on the top surface of the first dielectric structure, wherein the insulator layer is over the third conductive layer.

18. The integrated chip of claim 15, wherein the first dielectric structure is on a first portion of the first conductive interconnect and the first conductive layer is on a second portion of the first conductive interconnect, and wherein the second portion of the first conductive interconnect surrounds the first portion of the first conductive interconnect.

19. The integrated chip of claim 15, further comprising:
a second dielectric structure on the first conductive interconnect;
a third dielectric structure on the first conductive interconnect; and
a fourth dielectric structure on the first conductive interconnect,
wherein the wherein the first conductive layer, the insulator layer, and the second conductive layer form a three-dimensional capacitor which surrounds the first dielectric structure, the second dielectric structure, the third dielectric structure, and the fourth dielectric structure in a grid-shaped layout.

20. The integrated chip of claim 19, wherein an outer dielectric structure laterally surrounds the first dielectric structure, the second dielectric structure, the third dielectric structure, the fourth dielectric structure, and the three-dimensional capacitor, and wherein the first conductive layer covers sidewalls of the outer dielectric structure.
